(19) United States
(12) Patent Application Publication
(10) Pub. No.: US 2026/0106616 A1
(43) Pub. Date: Apr. 16, 2026

(54) SWITCHING TRANSDUCER DRIVER CIRCUITRY

(71) Applicant: Cirrus Logic International Semiconductor Ltd., Edinburgh (GB)

(72) Inventors: John P. LESSO, Edinburgh (GB); Scott P. WARRICK, Austin, TX (US); James T. DEAS, Edinburgh (GB)

(73) Assignee: Cirrus Logic International Semiconductor Ltd., Edinburgh (GB)

(21) Appl. No.: 19/422,791

(22) Filed: Dec. 17, 2025

Related U.S. Application Data
(63) Continuation-in-part of application No. 18/906,448, filed on Oct. 4, 2024.

(51) Int. Cl. H03K 17/687; H03F 3/217; H04R 3/00

(52) U.S. Cl. CPC H03K 17/6872; H03F 3/2171; H04R 3/00

(57) ABSTRACT

Switching driver circuitry comprising: a first half-bridge configured to switch an output node of the switching driver circuitry between a first supply voltage having a first magnitude and a second supply voltage having a second magnitude that is lower than the first magnitude; a second half-bridge configured to switch the output node between a third supply voltage having a magnitude that is equal to or lower than the second magnitude and a fourth supply voltage having a fourth magnitude that is lower than the third magnitude; and an isolation switch coupled to the first and second half-bridges and operable to isolate the second half-bridge from the first half-bridge.

### FIELD OF THE INVENTION

The present disclosure relates to switching transducer driver circuitry. In particular, the present disclosure relates to a switching output stage for class D amplifier circuitry.

### BACKGROUND

Switching transducer drivers such as Class D amplifiers are increasingly being used in electronic devices for which power efficiency is important, such as mobile telephones, portable media players, laptop and tablet computers, wireless headphones, earphones and earbuds. Such transducer drivers are also increasingly finding use in automotive applications, e.g. in vehicle audio systems and the like.

A typical switching transducer driver (e.g. a Class D amplifier) includes a modulator stage and an output stage. In low-power applications such as portable audio devices it is common for the output stage to be implemented as a full-bridge output stage, with a load such as a speaker being coupled in a bridge-tied load configuration between first and second half-bridges, each of which comprises first and second series-connected switches such as MOSFETs.

FIG. 1 is a simplified schematic representation of a full bridge output stage 100 comprising a first half-bridge 110 and a second half-bridge 120, which together provide a differential output voltage VOut for driving a bridge-tied load 130 (e.g. a loudspeaker) that can be coupled between respective output nodes 112, 122 of the first and second half-bridges 110, 120.

The first half-bridge 110 comprises a high-side switch 114 coupled in series with a complementary low-side switch 116 between a first supply voltage (VDD) rail 142 and a reference voltage (e.g. ground) rail 144 of the output stage 100. The high-side switch 114 and the low-side switch 116 may be, for example, complementary MOSFET devices.

Similarly, the second half-bridge 120 comprises a high-side switch 124 coupled in series with a complementary low-side switch 126 between the first supply voltage (VDD) rail 142 and the reference voltage (e.g. ground) rail 144 of the output stage 100. Again, the high-side switch 124 and the low-side switch 126 may be, for example, complementary MOSFET devices.

It will be appreciated by those skilled in the art that a practical implementation of the switching driver circuitry 100 may include first output low-pass filter circuitry between the output node 112 of the first half-bridge 110 and the load 130 and second output low-pass filter circuitry between the output node 122 of the second half-bridge and the load 130. The first and second output low-pass filter circuitry are typically LC filters (i.e. comprise an inductor and a capacitor). Such filter circuitry is not shown in FIG. 1 for the sake of clarity.

In use of the output stage 100, control signals such as pulse width modulated (PWM) signals are supplied to control terminals (e.g. gate terminals) of the high-side switch 114 and low-side switch 116 of the first half-bridge 110, and to control terminals (e.g. gate terminals) of the high-side switch 124 and the low-side switch 126 of the second half-bridge 120. The control signals are arranged such that when the high-side switch 114 is switched on in response to a control signal at its control terminal, the low-side switch 116 is switched off, and vice versa. Thus, in operation of the first half-bridge 110, the output node 112 will be at either the first supply voltage (VDD) or the reference voltage (e.g. ground), depending upon whether the high-side switch 114 or the low-side switch 116 is switched on. Similarly, in operation of the second half-bridge 120, the output node 122 will be at either the first supply voltage (VDD) or the reference voltage (e.g. ground), depending upon whether the high-side switch 124 or the low-side switch 126 is switched on. The output voltage VOut across the load 130 can thus take any of three levels: +VDD, −VDD or 0V (assuming that the reference voltage rail 144 is coupled to ground).

In some low-power applications the output stage 100 may be implemented in integrated circuitry (e.g. in a single integrated circuit) comprising the switches 114, 116, 124, 126. In some examples, such integrated circuitry may also comprise modulator circuitry for supplying the control signals to the switches 114, 116, 124, 126 of the output stage 100.

In higher power applications (e.g. automotive audio applications) it may be beneficial to use a single-ended output stage of the kind shown schematically in FIG. 2.

As shown in FIG. 2, the single-ended output stage 200 in this example comprises a half-bridge 210 having a high-side switch 212 coupled in series with a complementary low-side switch 214 between a first, positive (+VDD) supply voltage rail 222 and a second, negative (−VDD) supply voltage rail 224 of the single-ended output stage 200. The high-side switch 212 and the low-side switch 214 may be, for example, complementary MOSFET devices.

In use of the single-ended output stage 200, a load 230 such as a loudspeaker is coupled between an output node 216 of the half-bridge 210 and a reference voltage (e.g. ground) rail 226 of the single-ended output stage 200. In the example shown in FIG. 2 low-pass filter circuitry 240 comprising an inductor 242 and a capacitor 244 is coupled between the output node 216 and the load 230, to attenuate high frequency components that may be present in an output signal of the half-bridge 210 due to the switching frequency of the switches 212, 214.

Unlike the full bridge output stage 100 of FIG. 1, the single-ended output stage 200 of FIG. 2 requires a negative (−VDD) supply voltage rail 224. As will be appreciated by those skilled in the art, this may increase the complexity of the single-ended output stage 200, as compared to the full bridge output stage 100 of FIG. 1. However, the single-ended output stage 200 may be more cost effective than the full bridge output stage 100. In particular, where multiple channels are required (e.g. in an application such as a multi-channel audio system where multiple different loads such as loudspeakers are to be driven) it may be more cost effective to use one single-ended output stage of the kind shown in FIG. 2 per channel, with the negative (−VDD) supply voltage rail 224 being shared between all the channels, than to provide multiple full bridge output stages.

In operation of the single-ended output stage 200, control signals (e.g. PWM signals) are supplied to control terminals (e.g. gate terminals) of the high-side switch 112 and low-side switch 114 of the half-bridge 210. The control signals are arranged such that when the high-side switch 212 is switched on in response to a control signal at its control terminal, the low-side switch 214 is switched off, and vice versa. Thus, in operation of the half-bridge 210, the output node 216 will be at either the first supply voltage (+VDD) or the second supply voltage (−VDD), depending upon whether the high-side switch 212 or the low-side switch 214 is switched on. The output voltage VOut across the load 230 can thus take one of two levels: +VDD or −VDD.

In some examples the single-ended output stage 200 may be implemented in integrated circuitry (e.g. as a single integrated circuit incorporating the high-side switch 212 and the low-side switch 214, and perhaps also modulator circuitry for generating the control signals that are supplied to the switches 212, 214), but the low-pass filter circuitry 240 is typically implemented using discrete components that are not implemented in integrated circuitry—i.e. the inductor 242 and capacitor 244 of the low-pass filter circuitry 240 are typically off-chip devices. However, in other examples the single-ended output stage 200 may be implemented entirely using off-chip devices, particularly in high-power applications where the cost of on-chip switches may be greater than that of off-chip switches.

FIG. 3 is a schematic representation of switching driver circuitry capable of generating a three-level output voltage. In the example shown generally at 300 in FIG. 3, the switching driver circuitry implements Class D amplifier circuitry, and includes a half-bridge 310 comprising a high-side switch 312 and a low-side switch 314 coupled in series between a first, positive (+VDD) power supply rail 322 and a second, negative (−VDD) power supply rail 324, with an output node 316 of the half-bridge 310 being coupled, via low-pass filter circuitry 340 (which comprises an inductor 342 and a capacitor 344) to a first terminal of a load 330, the load having a second terminal coupled to a reference voltage (e.g. ground) rail 326.

The Class D amplifier circuitry 300 of FIG. 3 further comprises a third switch 350, having an input terminal coupled to the reference voltage (e.g. ground) rail 326 and an output terminal coupled to the output node 316 of the half-bridge 310.

The Class D amplifier circuitry 300 further comprises control circuitry 360 configured to control a mode of operation of the Class D amplifier circuitry 300.

In use of the Class D amplifier circuitry 300, control signals C1, C2, C3 are supplied by the control circuitry 360 to control terminals of the high-side switch 312, the low-side switch 314 and the third switch 350 respectively. The control signals C1, C2, C3 are arranged such that only one of the high-side switch 312, the low-side switch 314 and the third switch 350 can be switched on at once, so the output voltage VOut across the load 330 may take one of three values: +VDD (when the high-side switch 312 is switched on and the low-side switch 314 and the third switch 350 are both switched off), −VDD (when the low-side switch 314 is switched on and the high-side switch 312 and the third switch 350 are both switched off), or 0V (when the high-side switch 312 and the low-side switch 314 are both switched off and the third switch 350 is switched on). These three output voltage values may be used to encode three different values. For example, an output voltage of +VDD may represent a value of +1, an output voltage of −VDD may represent a value of −1 and an output voltage of 0 may represent a value of 0. The Class D amplifier circuitry 300 is thus capable of operating in a first mode with two output voltage levels, if the third switch 350 is held open (i.e. switched off). The Class D amplifier circuitry 300 can also operate in a second mode with three output voltage levels.

### SUMMARY

According to a first aspect, the invention provides switching driver circuitry comprising: a first half-bridge configured to switch an output node of the switching driver circuitry between a first supply voltage having a first magnitude and a second supply voltage having a second magnitude that is lower than the first magnitude; a second half-bridge configured to switch the output node between a third supply voltage having a magnitude that is equal to or lower than the second magnitude and a fourth supply voltage having a fourth magnitude that is lower than the third magnitude; and an isolation switch coupled to the first and second half-bridges and operable to isolate the second half-bridge from the first half-bridge.

The switching driver circuitry may further comprise control circuitry configured to control operation of the first and second half-bridges and the isolation switch in response to an input signal received by the control circuitry.

The switching driver circuitry may be operable to switch the output node between either the first supply voltage and the second supply voltage or the third supply voltage and the fourth supply voltage, based on the input signal.

The switching driver circuitry may be operable in: a first mode in which the first half-bridge is operable to switch the output node between the first supply voltage and the second supply voltage; and a second mode in which the second half-bridge is operable to switch the output node between the third supply voltage and the fourth supply voltage, wherein the control circuitry is configured to control the mode of operation of the switching driver circuitry based on the input signal.

The control circuitry may be configured to cause the switching driver circuitry to operate in the first mode if a level of the input signal is equal to or greater than a first threshold, and to cause the switching driver circuitry to operate in the second mode if the level of the input signal is less than the first threshold.

The first half-bridge may comprise a first high-side switch and a first low-side switch. The first high-side switch and the first low-side switch may comprise bandgap devices or high electron mobility transistor (HEMT) devices.

The first high-side switch and the first low-side switch may be Gallium Nitride (GaN) switches.

The second half-bridge may comprise a second high-side switch and a second low-side switch. The second high-side switch and the second low-side switch may comprise CMOS switches.

The isolation switch may comprises bandgap device or a high electron mobility transistor (HEMT) device such as a GaN switch.

The isolation switch may comprise a HEMT-based back-to-back switch in either a common-source or common-drain configuration.

According to a second aspect, the invention provides an integrated circuit comprising: a low-power half-bridge comprising a high-side switch and a low-side switch coupled in series; and a half-bridge output terminal for coupling an output node of the low-power half-bridge to external high-power bridge circuitry, wherein the half-bridge is configured to switch the half-bridge output terminal between first low-power half-bridge supply voltage and a second low-power half-bridge supply voltage of a magnitude lower than a magnitude of the first low-power half-bridge supply voltage.

The integrated circuit may further comprise: control circuitry configured to control the high-side switch and the low-side switch of the low-power half-bridge and switches of the external high-power bridge circuitry; and control output terminals for coupling the control circuitry to control terminals of the external high-power bridge circuitry to permit operation of the external high-power bridge circuitry to be controlled by the control circuitry.

The high-side switch and the low-side switch may comprise CMOS switches.

The external high-power bridge circuitry may comprise a high-power half-bridge comprising a high-side switch and a low-side switch coupled in series. The high-power half-bridge may be configured to switch an output node of the high-power half bridge between a first high-power half-bridge supply voltage and a second high-power half-bridge supply voltage having a magnitude that is greater than the magnitude of the first high-power half-bridge supply voltage. The external high-power bridge circuitry may further comprise an isolation switch configured to be coupled to the half-bridge output terminal and to selectively isolate the low-power half-bridge from the high-power half-bridge.

The isolation switch may comprise a HEMT-based back-to-back switch in either a common-source or common-drain configuration.

The high-side switch and the low-side switch of the external high-power bridge circuitry may comprise bandgap devices or high electron mobility transistor (HEMT) devices.

The high-side switch and the low-side switch of the external high-power bridge circuitry may be Gallium Nitride (GaN) switches.

The low-power half-bridge may be operable to switch the first low-power half-bridge supply voltage and a second low-power half-bridge supply voltage in response to control signals received from control circuitry when a level of an input signal received by the control circuitry is below a first threshold.

According to a third aspect, the invention provides a host device comprising the integrated circuit of the second aspect.

The host device may comprise a laptop, notebook, netbook or tablet computer, a gaming device, a games console, a controller for a games console, a virtual reality (VR) or augmented reality (AR) device, a mobile telephone, a portable audio player, a portable device, an accessory device for use with a laptop, notebook, netbook or tablet computer, a gaming device, a games console a VR or AR device, a mobile telephone, a portable audio player or other portable device.

Throughout this specification the word “comprise”, or variations such as “comprises” or “comprising”, will be understood to imply the inclusion of a stated element, integer or step, or group of elements, integers or steps, but not the exclusion of any other element, integer or step, or group of elements, integers or steps.

### BRIEF DESCRIPTION OF DRAWINGS

Embodiments of the invention will now be described, strictly by way of example only, with reference to the accompanying drawings, of which:

FIG. 1 is a schematic representation of a full-bridge output stage for use as a Class D amplifier output stage;

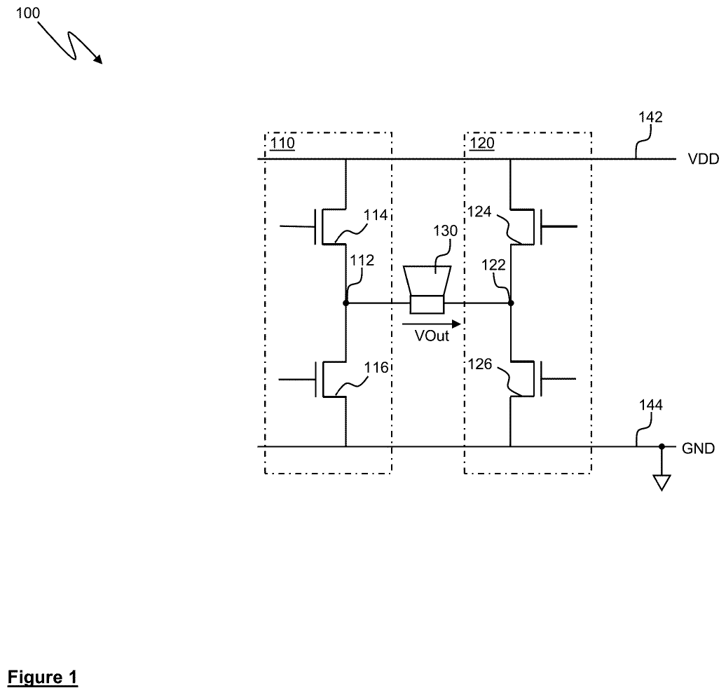

FIG. 2 is a schematic representation of a half-bridge output stage for use as a Class D amplifier output stage;

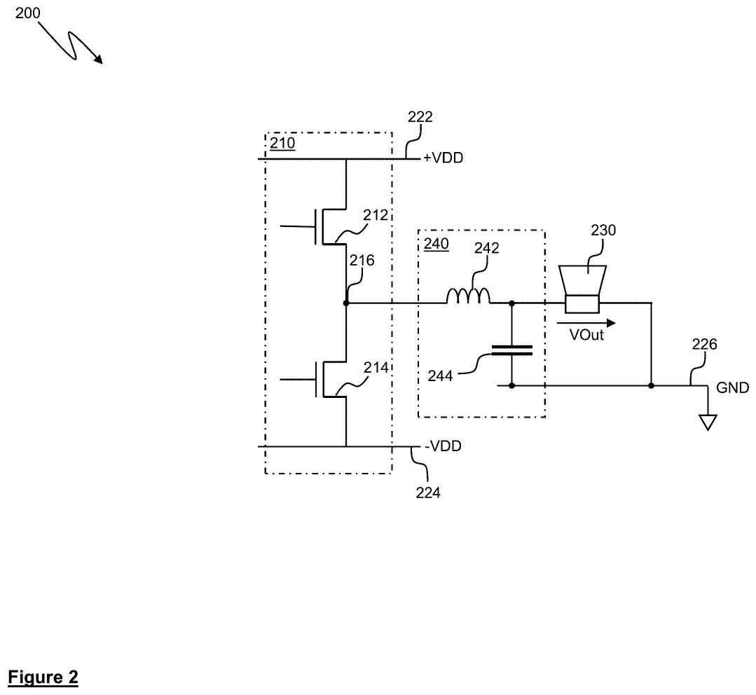

FIG. 3 is a schematic representation of switching transducer driver circuitry capable of generating a three-level output voltage;

FIG. 4 is a schematic representation of example switching transducer driver circuitry according to the present disclosure;

FIG. 5 is a schematic representation of alternative example switching transducer driver circuitry according to the present disclosure;

FIG. 6 is a schematic representation of an example arrangement for generating a second supply voltage for switching transducer driver circuitry according to the present disclosure;

FIG. 7 is a schematic representation of an alternative example arrangement for generating a second supply voltage for switching transducer driver circuitry according to the present disclosure;

FIG. 8 is a schematic representation of further example switching transducer driver circuitry according to the present disclosure;

FIG. 9 is a schematic representation of further example switching transducer driver circuitry according to the present disclosure;

FIG. 10 is a schematic representation of further example switching transducer driver circuitry according to the present disclosure;

FIG. 11 is a schematic representation of a further example arrangement for generating a second supply voltage for switching transducer driver circuitry according to the present disclosure;

FIG. 12 is a schematic representation of a control loop for the switching transducer circuitry of the present disclosure;

FIG. 13 is a schematic representation of further example switching transducer driver circuitry according to the present disclosure; and

FIG. 14 is a schematic representation of further example switching transducer driver circuitry according to the present disclosure.

### DETAILED DESCRIPTION

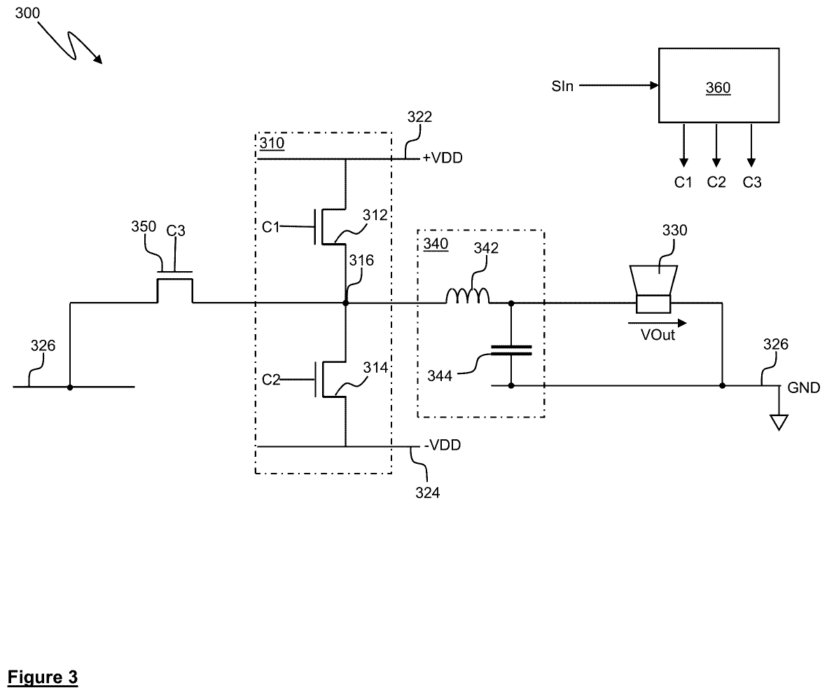

In low-power applications such as portable audio devices, the switches 312, 314 of the half-bridge 310 and the third switch 350 of the Class D amplifier circuitry 300 of FIG. 3 may be implemented by CMOS devices such as MOSFETs. For higher power applications such as automotive audio applications, where the switches 312, 314 may be required to switch relatively high voltages (e.g. greater than 60 volts DC), it may not be feasible to implement the switches 312, 314 of the half-bridge with CMOS devices, due to limitations in the maximum drain to source voltage (Vds) that can be supported by such devices and the high complexity of analog design for CMOS processes operating at such voltages.

Thus, in such higher power applications the switches 312, 314 of the half-bridge 310 may be implemented using devices that are capable of supporting higher voltages, such as wide bandgap devices or high electron mobility transistor (HEMT) devices based on, for example, Gallium Nitride (GaN), Silicon Carbide (SiC), Gallium Oxide (Ga₂0₃) or other semiconductor materials. Such devices are typically capable of operation at higher voltages, higher temperatures and higher frequencies than silicon-based switches such as MOSFETs.

However, the use of higher supply voltages can limit the dynamic range of the switching driver circuitry. In general, the output voltage VOut of three-level Class D amplifier circuitry of the kind shown generally at 300 in FIG. 3 is defined by the product of a duty cycle d of the control signals C1, C2 applied to the switches 312, 314 of the half-bridge 310 and the supply voltage, i.e. VOut=d×VDD. It follows from this that accurate control of the output voltage VOut requires that the duty cycle d is variable between a very low value (i.e. on-pulses of very short duration) and a much higher value (i.e. on-pulses of much longer duration). For example, if an output voltage VOut of 1 millivolt were required from the Class D amplifier circuitry 300 and the supply voltage VDD were 100 volts, a duty cycle d of 0.00001 would be required, whereas an output voltage VOut of 50 volts would require a much lower duty cycle d of 0.5.

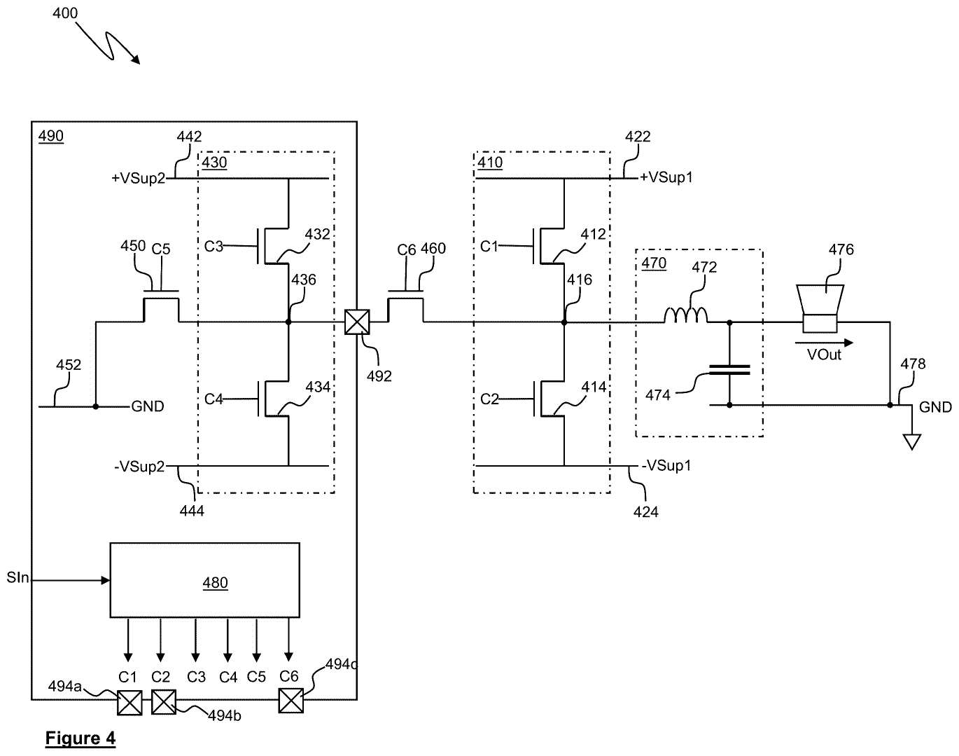

FIG. 4 is a schematic representation of switching driver circuitry according to the present disclosure.

In the example shown generally at 400 in FIG. 4, the switching driver circuitry implements Class D amplifier circuitry, and includes a first half-bridge 410 comprising a first high-side switch 412 and a first low-side switch 414 coupled in series between a first positive power supply rail 422 that receives a first positive power supply voltage +VSup1 from a power supply (not shown) and a first negative power supply rail 424 that receives a first negative power supply voltage −VSup1 from the power supply.

The first half-bridge 410 is configured to switch relatively high voltages, and may thus be termed a “high-power half-bridge”. For example, the magnitude of the first positive power supply voltage +VSup1 and the first negative power supply voltage −VSup1 may be of the order of 60 volts or more. The first high-side switch 412 and the first low-side switch 414 are capable of supporting such relatively high voltages. The first high-side switch 412 and the first low-side switch 414 may be, for example, wide bandgap devices or high electron mobility transistor (HEMT) devices based on, for example, Gallium Nitride (GaN), Silicon Carbide (SiC), Gallium Oxide (Ga₂0₃) or other semiconductor materials. In a particular example, the high-side switch 412 and the low-side switch 414 are GaN switches.

The switching driver circuitry 400 further includes a second half-bridge 430 comprising a second high-side switch 432 and a second low-side switch 434 coupled in series between a second positive power supply rail 442 that receives a second positive power supply voltage +VSup2 and a second negative power supply rail 444 that receives a second negative power supply voltage −VSup2. The second power supply voltages +/−VSup2 may be derived from the first power supply voltages +/−VSup1 as will be explained below.

The second half-bridge 430 is configured to switch lower voltages than the first half-bridge 410, and may thus be termed a “low-power half-bridge”. For example, the magnitude of the second positive power supply voltage +VSup2 and the second negative power supply voltage −VSup2 may be of the order of 12 volts or less. The second high-side switch 432 and the second low-side switch 434 are capable of supporting such voltages and may be implemented, for example, using silicon-based MOSFETs.

The switching driver circuitry 400 further comprises a ground switch 450, having an input terminal coupled to a ground rail 452 that receives a ground reference voltage (i.e. 0 volts) and an output terminal coupled to an output node 436 of the second half-bridge 430, between the second high-side switch 432 and the second low-side switch 434. The ground switch 450 may be implemented, for example, using a CMOS device such as a silicon-based MOSFET.

The switching driver circuitry 400 further comprises an isolation switch 460, having an input terminal coupled to the output node 436 of the second half-bridge 430 and an output terminal coupled to an output node 416 of the first half-bridge 410, between the first high-side switch 412 and the second high-side switch 424. The isolation switch 460 is operable to isolate the second half-bridge 430 from the first half-bridge 410, such that the first positive and negative supply voltages +VSup1, −VSup1 (which could damage the switches 432, 434 of the second half-bridge 430) are not transmitted to the second half-bridge 430. The isolation switch 460 is capable of supporting relatively high voltages of the kind supplied by the first positive and negative supply rails 422, 424. In particular, the isolation switch 460 is configured such that, when switched off, such relatively high voltages cannot pass from the first half-bridge 410 to the second half-bridge 430. The isolation switch 460 may be, for example, a wide bandgap device or a high electron mobility transistor (HEMT) device based on, for example, Gallium Nitride (GaN), Silicon Carbide (SiC), Gallium Oxide (Ga₂0₃) or other semiconductor materials. The isolation switch 460 need not be of the same type as the switches 412, 424 of the first half-bridge 410. For example, the switches 412, 424 of the first half-bridge 410 may be GaN switches, and the isolation switch 460 may be a SiC switch.

In use of the switching driver circuitry 400, the output node 416 of the first half-bridge 410 is coupled, via low-pass filter circuitry 470 (which comprises an inductor 472 and a capacitor 474) to a first terminal of a load 476, the load 476 having a second terminal coupled to a reference voltage (e.g. ground) rail 478.

The switching driver circuitry 400 further comprises control circuitry 480 (which may also be referred to as modulator circuitry) configured to control the operation of the switching driver circuitry 400 based on an input signal SIn, received by the control circuitry 480, that represents a signal to be amplified by the switching driver circuitry 400.

In use of the switching driver circuitry 400, control signals C1, C2 are supplied by the control circuitry 480 to control terminals of the first high-side switch 412 and the first low-side switch 414, respectively, to control operation of the first high-side switch 412 and the first low-side switch 414. Similarly, control signals C3, C4, C5 are supplied by the control circuitry 480 to control terminals of the second high-side switch 432, the second low-side switch 434 and the ground switch 450, respectively, to control operation of the second high-side switch 432, the second low-side switch 434 and the ground switch 450. A further control signal C6 is supplied by the control circuitry 480 to the isolation switch 460, to control operation of the isolation switch 460.

The switching driver circuitry 400 is operable in a first mode (which may be referred to as a high-power output mode) in which the isolation switch 460 is open (switched off) and the first half-bridge 410 supplies either the first positive supply voltage +VSup1 or the first negative supply voltage −VSup1 to the load 476. In the first mode, the control signal C6 is supplied to the isolation switch 460 to turn the isolation switch 460 off, thus decoupling and isolating the second half-bridge 430 from the first half-bridge 410. The control signals C1, C2 output by the control circuitry 480 in the first mode are arranged such that only one of the first high-side switch 412 and the first low-side switch 414 can be switched on at once. Thus, in the first mode, the output voltage VOut supplied across the load 476 by the first half-bridge 410 may take one of two values: +VSup1 (when the first high-side switch 412 is switched on and the first low-side switch 414 is switched off), and −VSup1 (when the first low-side switch 414 is switched on and the first high-side switch 412 is switched off). In the first mode, the control signals C3, C4 supplied to the second high-side switch 432 and the second low-side switch 434, respectively, may cause the second high-side switch 432 and the second low-side switch 434 to be held open (i.e. switched off), and the control signal C5 supplied to the ground switch 450 may cause the ground switch 450 to be closed (i.e. switched on).

The switching driver circuitry 400 is also operable in a second mode (which may be referred to as a low-power output mode), in which the isolation switch 460 is closed (i.e. switched on) in response to a suitable control signal C6, and the combination of the second half-bridge 430 and the ground switch 450 supplies either the second positive supply voltage +VSup2, 0V, or the second negative supply voltage −VSup2 to the load 476. In the second mode, the control signal C6 is supplied to the isolation switch 460 to turn the isolation switch 460 on, thus coupling the output node 436 of the second half-bridge 430 to the load 476 (via the low-pass filter 470). The control signals C3, C4, C5 output by the control circuitry 480 in the second, low-power output mode are arranged such that only one of the second high-side switch 432, the second low-side switch 434 and the ground switch 450 can be switched on at once. Thus, in the second mode, the output voltage VOut supplied across the load 486 by the combination of the second half-bridge 430 and the ground switch 450 may take one of three values: +VSup2 (when the second high-side switch 432 is switched on and the second low-side switch 434 and the ground switch 450 are both switched off), −VSup2 (when the second low-side switch 434 is switched on and the second high-side switch 432 and the ground switch 450 are both switched off), and 0V (when the second high-side switch 432 and the second low-side switch 434 are switched off and the ground switch 450 is switched on). In the second mode, the control signals C1, C2 supplied to the first high-side switch 412 and the first low-side switch 414, respectively, may cause the first high-side switch 412 and the first low-side switch 414 to be held open (i.e. switched off).

The control circuitry 480 is configured to control the mode of operation of the switching driver circuitry 400 based on a level (e.g. a magnitude, envelope or volume) of the input signal SIn received by the control circuitry 480. The control circuitry 480 may be configured to compare the level if the input signal SIn to a first threshold and, based on the result of this comparison, cause the switching driver circuitry 400 to operate in either its first (high-power output) mode or its second (low-power output) mode.

For example, if the level of the input signal SIn is equal to or greater than the first threshold, this may be indicative that an output voltage VOut across the load 476 of a magnitude greater than that of the second supply voltage VSup2 is required for the load 476 to generate an output signal of a desired magnitude (e.g. an audio output of a desired volume) and thus cannot be supplied by the second half-bridge 430.

Thus, if the level of the input signal SIn is equal to or greater than the first threshold, the control circuitry 480 may cause the switching driver circuitry 400 to operate in its first (high-power output) mode, by outputting a suitable control signal C6 to switch off the isolation switch 460 and outputting suitable control signals C1, C2 to control the first high-side switch 412 and the first low-side switch 414 to generate the required output voltage VOut across the load 476.

In contrast, if the level of the input signal SIn is lower than the first threshold, this may be indicative that the magnitude of the output voltage VOut across the load 476 required for the load 476 to generate an output signal of a desired magnitude (e.g. an audio output of a desired volume) is less than (or equal to) that of the second supply voltage VSup2 and can thus be supplied by the second half-bridge 430.

Thus, if the level of the input signal is less than the first threshold, the control circuitry 480 may cause the switching driver circuitry 400 to operate in its second (low-power output) mode, by outputting a suitable control signal C6 to switch on the isolation switch 460, and outputting suitable control signals C3, C4, C5 to control the second high-side switch 432, the second low-side switch 434 and the ground switch 450 to generate the required output voltage VOut across the load 476.

If the level of the input signal is zero (or less than a second threshold that is lower than the first threshold), this may be indicative that no output signal is required, such that the switching driver circuitry 400 can operate in a quiescent mode in which no output voltage VOut is supplied to the load 476.

Thus, if the level of the input signal is zero (or less than the second threshold), the control circuitry 480 may output a suitable control signal C6 to switch on the isolation switch 460, and output a suitable control signal C5 to switch on the ground switch 450, and output suitable control signals C1, C2, C3, C4 to switch off the first high-side switch 412, the first low-side switch 414, the second high-side switch 432 and the second low-side switch 434. With the switches 412, 414, 432, 434, 450, 460 in this configuration, the output node 416 of the first half-bridge 410 is coupled to ground, such that no output voltage VOut develops across the load 476. This effectively implements a mute mode for extremely small input signals.

By selecting between the first (high-power output) mode and the second (low-power output) mode based on the level of the input signal SIn, the switching driver circuitry 400 of FIG. 4 is capable of efficiently supplying a highly accurate output voltage over a wide range. In particular, operating the Class D amplifier circuitry 400 in its second mode when the level of the input signal SIn is less than the first threshold (and in the quiescent mode when the input signal level is zero or less than the second threshold) and in its first mode when the level of the input signal SIn is equal to or greater than the first threshold ensures that there is minimal unnecessary headroom in the supply voltage that is switched to provide the output voltage VOut to the load 476, while also enabling highly accurate control of the magnitude of the output voltage without requiring excessively low duty cycles for the control signals C1-C4 that control the switches 412, 414, 432, 434 of the first and second half-bridges 410, 430.

For example, if an output voltage VOut of 1 millivolt were required, the switching driver circuitry 400 would operate in its second mode using the second half-bridge 430 to switch the second supply voltage +/−VSup2. If the magnitude of VSup2 were 10 volts, a duty cycle d of 0.0001 would be required for switching the switches 432, 434. In contrast, if an output voltage VOut of 50 volts were required, the switching driver circuitry 400 would operate in its first mode using the first half-bridge 410 to switch the first supply voltage +/−VSup1. If the magnitude of VSup1 were 100 volts, a duty cycle d of 0.5 would be required for switching the switches 432, 434.

In some examples, the second half-bridge 430, the ground switch 450 and the control circuitry 480 may be provided on a single IC 490, while the first half-bridge 410 and the isolation switch 460 are external to the IC 490. In such examples, the control terminals of the second high-side switch 432, second low-side switch 434 and ground switch 450 may be coupled, internally of the IC 490, to appropriate outputs of the control circuitry 480, and the IC 490 may be provided with a half-bridge output terminal 492 for coupling the output node 436 to the input terminal of the external isolation switch 460, and with control output terminals 494a-494c for coupling outputs of the control circuitry 480 to control terminals of the first high-side switch 412 and the first low-side switch 414 of the external first half-bridge 410.

Thus, such an IC includes an internal half-bridge (the second half-bridge 430) capable of switching a first voltage (the second supply voltage VSup2), the ground switch 450, and the control circuitry 480. The control circuitry 480 is configured to control operation of the internal half-bridge 430, the ground switch 450 and an external half-bridge (the first half-bridge 410) that is capable of switching a second voltage (the first supply voltage VSup1) of higher magnitude than the first voltage.

Such an IC (which may be referred to as a “bridge driver IC” or simply a “driver IC” or an “amplifier IC”) is thus capable of operation, in relatively low-power applications, as a standalone driver for driving a load such as an audio output transducer (e.g. a speaker), a haptic output transducer (e.g. a resonant actuator) or the like with a two- or three-level signal, or in combination with another such IC in a bridge-tied load configuration for driving such a load. Additionally, because such an IC includes the control circuitry 480, it is also capable of operation, in higher-power applications, for controlling an external high-power output stage such as the first half-bridge 410 described above with reference to FIG. 4.

In other examples, the second half-bridge 430 and the ground switch 450 may be provided on a single integrated circuit (IC) 490, but the control circuitry 480 may be external to the IC 490, as well as the first half-bridge 410 and the isolation switch 460. In such examples, the IC 490 is provided with input terminals for receiving the control signals C3, C4 and C5 for the second high-side switch 432, the second low-side switch 434 and the ground switch 450 from the external control circuitry 480, and with a half-bridge output terminal 492 for coupling the output node 436 to the input terminal of the external isolation switch 460.

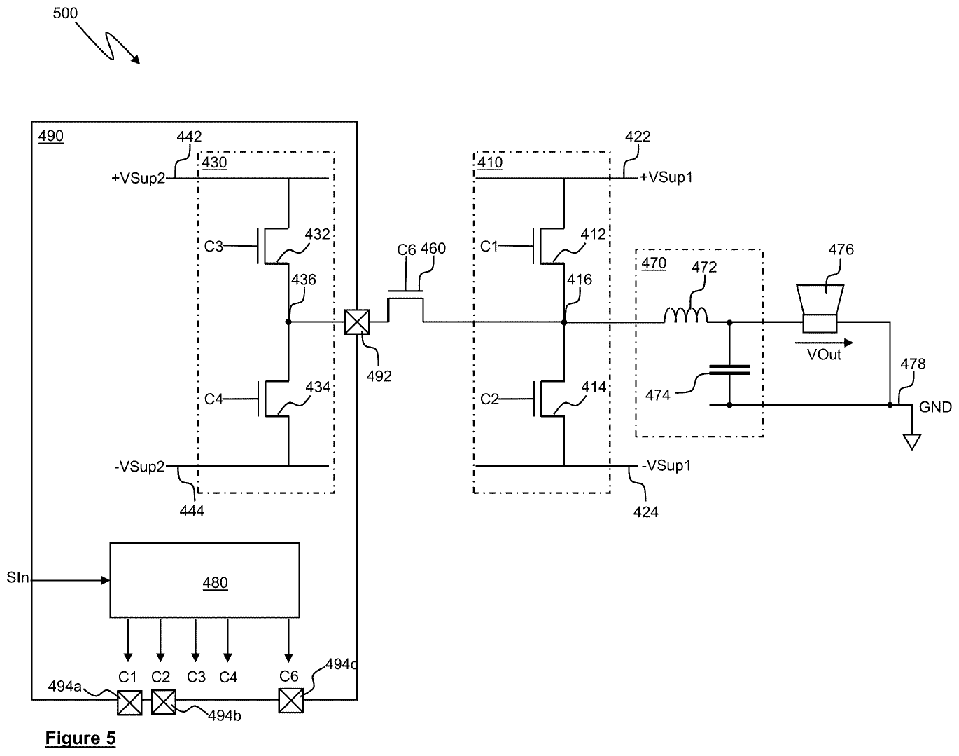

FIG. 5 is a schematic representation of alternative switching driver circuitry according to the present disclosure.

The alternative switching driver circuitry shown generally at 500 in FIG. 5 is similar to, and has a number of elements in common with the switching driver circuitry 400 of FIG. 4. Such common elements are denoted by common reference numerals in FIGS. 4 and 5 and will not be described in detail here, for the sake of clarity and brevity.

The alternative switching driver circuitry 500 of FIG. 5 differs from the switching driver circuitry 400 of FIG. 4 in that it does not include the ground switch 450. Thus, when operating in the second (low-power output) mode of operation, the alternative switching driver circuitry 500 can supply only a two-level output voltage VOut to the load 476, by switching the output node 436 of the second half-bridge 430 between the second positive supply voltage +VSup2 and the second to negative supply voltage −VSup2 by appropriate control of the second high-side switch 432 and the second low-side switch 434.

Thus the alternative switching driver circuitry 500 is not able to operate in the quiescent mode described above with reference to FIG. 4 when the level of the input signal SIn is zero or less than a second threshold, and thus the quiescent power consumption of the alternative switching driver circuitry 500 may be greater than that of the switching driver circuitry 400.

However, the alternative switching driver circuitry 500 is simpler than the switching driver circuitry 400, as a feedback loop may be required in order to avoid or suppress distortion in the output generated by the load 476 in the three-level arrangement provided by the combination of the second half-bridge 430 and the ground switch 450 of the switching driver circuitry 400 of FIG. 4. In contrast, the two-level arrangement provided by the second half-bridge 430 of FIG. 5 (without a ground switch) is capable of open-loop operation without introducing distortion in the output generated by the load 476. Thus, the alternative switching driver circuitry 500 represents a compromise between reduced design complexity and increased quiescent power consumption.

As will be appreciated by those of ordinary skill in the art, the second positive and negative supply voltages +VSup2, −VSup2 can be generated in a variety of different ways.

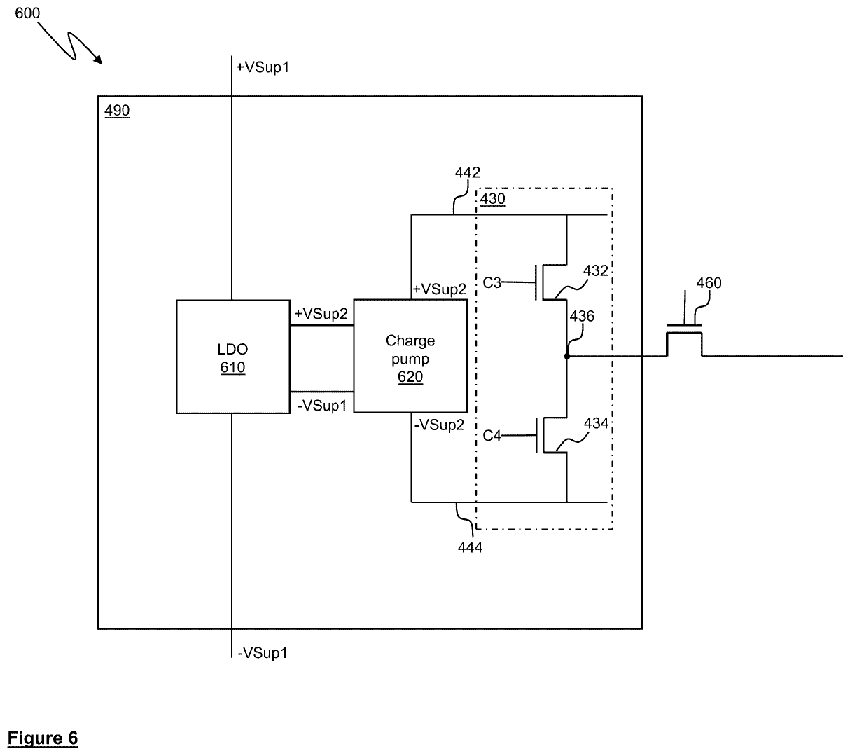

FIG. 6 is a schematic representation of an arrangement for generating the second positive and negative supply voltages +VSup2, −VSup2 from the first positive and negative supply voltages +VSup1, −VSup1. In the arrangement shown generally at 600 in FIG. 6, low drop-out regulator (LDO) circuitry 610 receives the first positive and negative supply voltages +VSup1, −VSup1 and generates the second positive supply voltage +VSup2, which is supplied to charge pump circuitry 620 and to the second positive power supply rail 442. The charge pump circuitry 620 generates the second negative supply voltage −VSup2, and outputs it to the second negative power supply rail 444.

The second positive and negative supply voltages +VSup2, −VSup2 may be between 0.1× and 0.3× the first positive and negative supply voltages +VSup1, −VSup1 (i.e. if +/−VSup1 is 100 volts, +/−VSup2 is between 10 volts and 30 volts). In some examples, the second positive and negative supply voltages +VSup2, −VSup2 are of the order of 0.2× the first positive and negative supply voltages +VSup1, −VSup1 (i.e. if +/−VSup1 is 100 volts, +/−VSup2 is of the order of 20 volts). In other examples, the second positive and negative supply voltages +VSup2, −VSup2 are of the order of one-sixth of the first positive and negative supply voltages +VSup1, −VSup1 (i.e. if +/−VSup1 is 100 volts, +/−VSup2 is of the order of 16.67 volts).

The LDO circuitry 610 may be implemented as part of an IC 490 that also implements the second half-bridge 430, as shown in FIG. 6, or alternatively may be external to the IC 490.

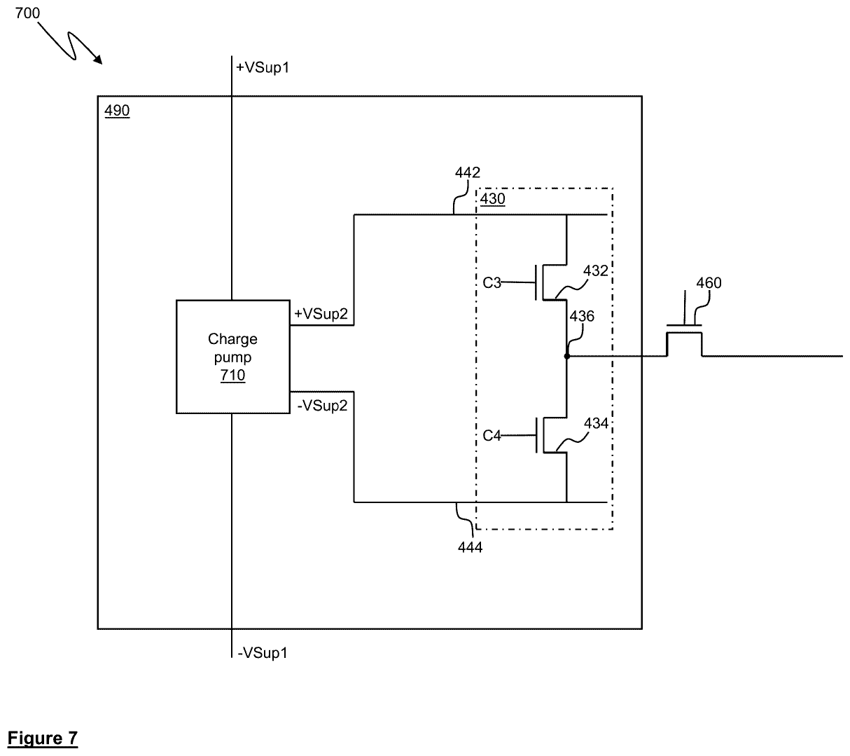

FIG. 7 is a schematic representation of an alternative arrangement for generating the second positive and negative supply voltages +VSup2, −VSup2 from the first positive and negative supply voltages +VSup1, −VSup1. In the arrangement shown generally at 700 in FIG. 7, charge pump circuitry 710 receives the first positive and negative supply voltages +VSup1, −VSup1 and outputs the second positive and negative supply voltages +VSup2, −VSup2 to the second positive power supply rail 442 and the second negative power supply rail 444, respectively.

Again, the second positive and negative supply voltages +VSup2, −VSup2 may be between 0.1× and 0.3× the first positive and negative supply voltages +VSup1, −VSup1 (i.e. if +/−VSup1 is 100 volts, +/−VSup2 is between 10 volts and 30 volts). In some examples, the second positive and negative supply voltages +VSup2, −VSup2 are of the order of 0.2× the first positive and negative supply voltages +VSup1, −VSup1 (i.e. if +/−VSup1 is 100 volts, +/−VSup2 is of the order of 20 volts). In other examples, the second positive and negative supply voltages +VSup2, −VSup2 are of the order of one-sixth of the first positive and negative supply voltages +VSup1, −VSup1 (i.e. if +/−VSup1 is 100 volts, +/−VSup2 is of the order of 16.67 volts). Those skilled in the art will be familiar with charge pump topologies that can generate an output voltage that is between 0.1× and 0.3× its input voltage, an output voltage that is of the order of 0.2× its input voltage, and an output voltage that is of the order of one-sixth of its input voltage.

The charge pump circuitry 710 may be implemented as part of an IC 490 that also implements the second half-bridge 430, as shown in FIG. 7, or alternatively may be external to the IC 490.

In some applications it may be desirable to provide more than two half-bridges, with each half-bridge being configured to switch a supply voltage of a different magnitude.

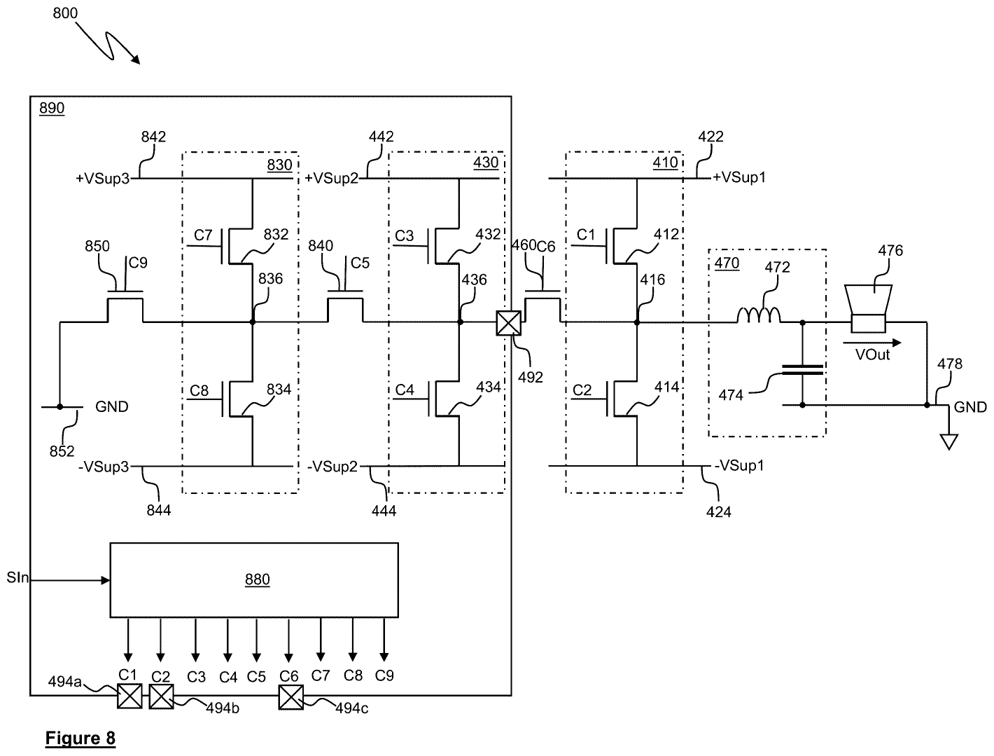

FIG. 8 is a schematic representation of example switching driver circuitry 800 including three half-bridges, but it will be appreciated that the principles described below are equally applicable to switching driver circuitry including four or more half-bridges.

The switching driver circuitry 800 of FIG. 8 implements Class D amplifier circuitry, and includes a first half-bridge 410 of the kind described above with reference to FIG. 4, configured to switch a relatively high supply voltage +/−VSup1. The first half-bridge 410 is coupled to a second half-bridge 430 of the kind described above with reference to FIG. 4, by an isolation switch 460 of the kind described above with reference to FIG. 4.

The switching driver circuitry 800 further comprises a third half-bridge 830, comprising a third high-side switch 832 and a third low-side switch 834 coupled in series between a third positive power supply rail 842 which receives a third positive power supply voltage +VSup3 and a third negative power supply rail which receives a third negative power supply voltage −VSup3. The third positive and negative power supply voltages +/−VSup3 may be of lower magnitude than the second positive and negative power supply voltages +/VSup2. For example, if the magnitude of +/−VSup2 is 12 volts, the magnitude of +/−VSup3 may be 5 volts. The switches 832, 834 of the third half-bridge 830 are typically able to support lower maximum drain to source voltages (Vds) than the switches 432, 434 of the second half-bridge.

The output node 436 of the second half-bridge 430 is coupled to an output node 836 (between the third high-side switch 832 and the third low-side switch 834) of the third half-bridge 830 by coupling switch 840. The output node 836 of the third half-bridge 830 is also coupled to a ground (i.e. 0V) supply rail 852 by a ground switch 852. Thus, when the coupling switch 840 and the ground switch 850 are both switched on, the output node 436 of the second half-bridge 430 is coupled to the ground supply rail 852.

The switching driver circuitry 800 further comprises control circuitry 880 (which may also be referred to as modulator circuitry) configured to control the operation of the switching driver circuitry 800, based on an input signal SIn, representing a signal to be amplified by the switching driver circuitry 800, received by the control circuitry 880.

In use of the switching driver circuitry 800, control signals C1, C2 are supplied by the control circuitry 880 to control terminals of the first high-side switch 412 and the first low-side switch 414, respectively, to control operation of the first high-side switch 412 and the first low-side switch 414. Similarly, control signals C3, C4, C5 are supplied by the control circuitry 880 to control terminals of the second high-side switch 432, the second low-side switch 434 and the coupling switch 840, respectively, to control operation of the second high-side switch 432, the second low-side switch 434 and the coupling switch 840. A further control signal C6 is supplied by the control circuitry 880 to the isolation switch 460 to control operation of the isolation switch 460, and further control signals C7, C8, C9 are supplied by the control circuitry 880 to control terminals of the third high-side switch 832, the third low-side switch 834 and the ground switch 850 to control operation of those switches.

The switching driver circuitry 800 is operable in a first (high-power output) mode in which the isolation switch 460 is open (switched off) and the first half-bridge 410 supplies either the first positive supply voltage +VSup1 or the first negative supply voltage −VSup1 to the load 476. In the first mode, the control signal C6 is supplied to the isolation switch 460 to turn the isolation switch 460 off, thus decoupling and isolating the second half-bridge 430 from the first half-bridge 410. The control signals C1, C2 output by the control circuitry 480 in the first mode are arranged such that only one of the first high-side switch 412 and the first low-side switch 414 can be switched on at once. Thus, in the first mode, the output voltage VOut supplied across the load 476 by the first half-bridge 410 may take one of two values: +VSup1 (when the first high-side switch 412 is switched on and the first low-side switch 414 is switched off), or −VSup1 (when the first low-side switch 414 is switched on and the first high-side switch 412 is switched off). In the first mode, the control signals C3, C4 supplied to the second high-side switch 432 and the second low-side switch 434, respectively, may cause the second high-side switch 432 and the second low-side switch 434 to be held open (i.e. switched off), and the control signal C5 supplied to the coupling switch 840 may cause the coupling switch 840 to be closed (i.e. switched on). Similarly, the control signals C7, C8 supplied to the third high-side switch 832 and the third low-side switch 834, respectively, may cause the third high-side switch 832 and the third low-side switch 834 to be held open (i.e. switched off), and the control signal C9 supplied to the second ground switch 850 may cause the second ground switch 850 to be closed (i.e. switched on).

The switching driver circuitry 800 is also operable in a second (lower-power output) mode, in which the isolation switch 460 is closed (i.e. switched on) in response to a suitable control signal C6, and the combination of the second half-bridge 430 and the coupling switch 840 and the ground switch 850 supplies either the second positive supply voltage +VSup2, 0V, or the second negative supply voltage −VSup2 to the load 476. In the second mode, the control signal C6 is supplied to the isolation switch 460 to turn the isolation switch 460 on, thus coupling the output node 436 of the second half-bridge 430 to the load 476 (via the low-pass filter 470). The control signals C3, C4, C5, C9 output by the control circuitry 480 in the second mode are arranged such that only one of the second high-side switch 432, the second low-side switch 434 and the combination of the coupling switch 840 and the ground switch 850 can be switched on at once. Thus, in the second mode, the output voltage VOut supplied across the load 476 by the combination of the second half-bridge 430 and the coupling switch 840 and the ground switch 850 may take one of three values: +VSup2 (when the second high-side switch 432 is switched on and the second low-side switch 434, the coupling switch 840 and the ground switch 850 are all switched off), −VSup2 (when the second low-side switch 434 is switched on and the second high-side switch 432 and the coupling switch 840 and the ground switch 850 are all switched off), or 0V, when the second high-side switch 432 and the second low-side switch 434 are switched off and the coupling switch 840 and the ground switch 850 are switched on. In the second mode, the control signals C1, C2 supplied to the first high-side switch 412 and the first low-side switch 414, respectively, may cause the first high-side switch 412 and the first low-side switch 414 to be held open (i.e. switched off). Similarly, the control signals C7, C8 supplied to the third high-side switch 832 and the third low-side switch 834 may cause the third high-side switch 832 and the third low-side switch 834 to be held open (i.e. switched off).

The switching driver circuitry 800 is also operable in a third (lowest-power output) mode, in which the isolation switch 460 is closed (i.e. switched on) in response to a suitable control signal C6, and the combination of the third half-bridge 830 and the ground switch 850 supplies either the third positive supply voltage +VSup3, 0V, or the third negative supply voltage −VSup3 to the load 476. In the third mode, the control signal C6 is supplied to the isolation switch 460 to turn the isolation switch 460 on, and the control signal C5 is supplied to the coupling switch 840 to turn the coupling switch 840 on, thus coupling the output node 836 of the third half-bridge 830 to the load 476 (via the low-pass filter 470). The control signals C7, C8, C9 output by the control circuitry 880 in the third mode are arranged such that only one of the third high-side switch 832, the third low-side switch 834 and the ground switch 850 can be switched on at once. Thus, in the third mode, the output voltage VOut supplied across the load 476 by the combination of the third half-bridge 830 and the ground switch 850 may take one of three values: +VSup3 (when the third high-side switch 832 is switched on and the third low-side switch 834 and the ground switch 850 are both switched off), −VSupl3 (when the third low-side switch 834 is switched on and the third high-side switch 832 and the ground switch 850 are both switched off), and 0V (when the third high-side switch 832 and the third low-side switch 834 are switched off and the ground switch 850 is switched on). In the third mode, the control signals C1, C2 supplied to the first high-side switch 412 and the first low-side switch 414, respectively, may cause the first high-side switch 412 and the first low-side switch 414 to be held open (i.e. switched off). Similarly, the control signals C3, C4 supplied to the second high-side switch 432 and the second low-side switch 434 may cause the second high-side switch 432 and the second low-side switch 434 to be held open (i.e. switched off).

As the switches 832, 834 of the third half-bridge 830 are “weaker” than those of the first and second half-bridges 410, 430, in that they are only capable of supporting drain to source voltages (Vds) that are lower than those that can be supported by the first and second half-bridges 410, 430, it is important, when operating the switching driver circuitry 800 in the third (lowest-power output) mode that the voltage at the output node 416 is small enough that it will not cause damage to the switches 832, 834. Thus, in operation of the switching driver circuitry 800, the voltage at the output node 416 should remain within the limits of the third power supply voltage VSup3 (i.e. between −VSup3 and +VSup3).

To this end, in operation of the switching driver circuitry 800, In the second mode, the control signals C1, C2 supplied to the first high-side switch 412 and the first low-side switch 414, respectively, may cause the first high-side switch 412 and the first low-side switch 414 to be held open (i.e. switched off). Similarly, the control signals C3, C4 supplied to the second high-side switch 432 and the second low-side switch 434 may cause the second high-side switch 432 and the second low-side switch 434 to be held open (i.e. switched off), such that the voltage at the output node 416 never exceeds +/−VSup3.

The control circuitry 880 is configured to control the mode of operation of the switching driver circuitry based on a level (e.g. a magnitude or envelope) of the input signal SIn received by the control circuitry 880. The control circuitry 880 may be configured to compare the level of the input signal SIn to first and second thresholds (where the second threshold is lower than the first threshold), and based on the results of these comparisons, cause the switching driver circuitry 800 to operate in either its first (high-power output) mode, its second (lower-power output) mode, or its third (lowest-power output) mode.

For example, if the level of the input signal SIn is equal to or greater than the first threshold, this may be indicative that an output voltage VOut across the load 476 of a magnitude greater than that of the second supply voltage VSup2 is required for the load 476 to generate an output signal of a desired magnitude (e.g. an audio output of a desired volume) and thus cannot be supplied by the second half-bridge 430.

Thus, if the level of the input signal SIn is equal to or greater than the first threshold, the control circuitry 880 may cause the switching driver circuitry 800 to operate in its first (high-power output) mode by outputting a suitable control signal C6 to switch off the isolation switch 460 and outputting suitable control signals C1, C2 to control the first high-side switch 412 and the first low-side switch 414 to generate the required output voltage VOut across the load 476.

If the level of the input signal SIn is lower than the first threshold, but equal to or greater than the second threshold, this may be indicative that the magnitude of the output voltage VOut across the load 476 required for the load 476 to generate an output signal of a desired magnitude (e.g. an audio output of a desired volume) is less than (or equal to) that of the second supply voltage VSup2 but greater than that of the third supply voltage VSup3, and can thus be supplied by the second half-bridge 430.

Thus, if the level of the input signal is less than the first threshold but equal to or greater than the second threshold, the control circuitry 880 may may cause the switching driver circuitry 800 to operate in its second (lower-power output) mode by outputting a suitable control signal C6 to switch on the isolation switch 460, and outputting suitable control signals C3, C4, C5, C9 to control the second high-side switch 432, the second low-side switch 434 and the coupling switch 840 and the ground switch 850 to generate the required output voltage VOut across the load 476.

If the level of the input signal SIn is lower than the second threshold, this may be indicative that the magnitude of the output voltage VOut across the load 476 required for the load 476 to generate an output signal of a desired magnitude (e.g. an audio output of a desired volume) is less than (or equal to) that of the third supply voltage VSup3, and can thus be supplied by the third half-bridge 830.

Thus, if the level of the input signal is less than the second threshold, the control circuitry 880 may may cause the switching driver circuitry 800 to operate in its third (lowest-power output) mode, by outputting a suitable control signal C6 to switch on the isolation switch 460, and outputting suitable control signals C7, C8, C9 to control the third high-side switch 832, the third low-side switch 834 and the ground switch 850 to generate the required output voltage VOut across the load 476.

If the level of the input signal is zero (or less than a third threshold that is lower than the second threshold), this may be indicative that no output signal is required, such that the switching amplifier circuitry 800 can operate in a quiescent mode in which no output voltage VOut is supplied to the load 476. Thus, if the level of the input signal is zero (or less than the third threshold), the control circuitry 880 may output a suitable control signal C6 to switch on the isolation switch 460, and may output suitable control signals C5, C9 to switch on the coupling switch 840 and the ground switch 850, and may output suitable control signals C1, C2, C3, C4, C7, C8 to switch off the first high-side switch 412, the first low-side switch 414, the second high-side switch 432, the second low-side switch 434, the third high-side switch 832 and the third low-side switch 834. With the switches 412, 414, 432, 434, 840, 460, 832, 834, 850 in this configuration, the output node 416 of the first half-bridge 410 is coupled to ground, such that no output voltage VOut develops across the load 476.

By selecting between the first (high-power output) mode, the second (lower-power output) mode and the third (lowest-power output) mode based on the level of the input signal SIn, the switching driver circuitry of FIG. 8 is capable of efficiently supplying a highly accurate output voltage over a wide range. In particular, operating the Class D amplifier circuitry 800 in its second (lower-power output) mode when the level of the input signal SIn is less than the first threshold and in its third (lowest-power output) mode when the level of the input signal SIn is less than the second threshold (and in the quiescent mode when the input signal level is zero or less than the third threshold) and in its first (high-power output) mode when the level of the input signal SIn is equal to or greater than the first threshold ensures that there is minimal unnecessary headroom in the supply voltage that is switched to provide the output voltage VOut to the load 476, while also enabling highly accurate control of the magnitude of the output voltage without requiring excessively low duty cycles for the control signals C1-C4, C7, C8 that control the switches 412, 414, 432, 434, 832, 834, of the first, second and third half-bridges 410, 430, 830.

In some examples, the second and third half-bridges 430, 830, the coupling switch 840, the ground switch 850 and the control circuitry 880 may be provided on a single IC 890, while the first half-bridge 410 and the isolation switch 460 are external to the IC 890. In such examples, the control terminals of the second high-side switch 432, second low-side switch 434, the third high-side switch 832, the third low-side switch 834, the coupling switch 840 and the ground switch 850 may be coupled, internally of the IC 890, to appropriate outputs of the control circuitry 480, and the IC 890 may be provided with a half-bridge output terminal 492 for coupling the output node 436 to the input terminal of the external isolation switch 460, and with control output terminals 494a-494c for coupling outputs of the control circuitry 880 to control terminals of the first high-side switch 412 and the first low-side switch 414 of the external first half-bridge 410.

In other examples, the second and third half-bridges 430, 830, the coupling switch 840 and the ground switch 850 may be provided on a single integrated circuit (IC) 890, but the control circuitry 880 may be external to the IC 890, as well as the first half-bridge 410 and the isolation switch 460. In such examples, the IC 890 is provided with input terminals for receiving the control signals C3, C4, C7, C8, C5 and C9 for the second high-side switch 432, the second low-side switch 434, the third high-side switch 832, the third low-side switch 834, the coupling switch 840 and the ground switch 850 from the external control circuitry 880, and with a half-bridge output terminal 492 for coupling the output node 436 to the input terminal of the external isolation switch 460.

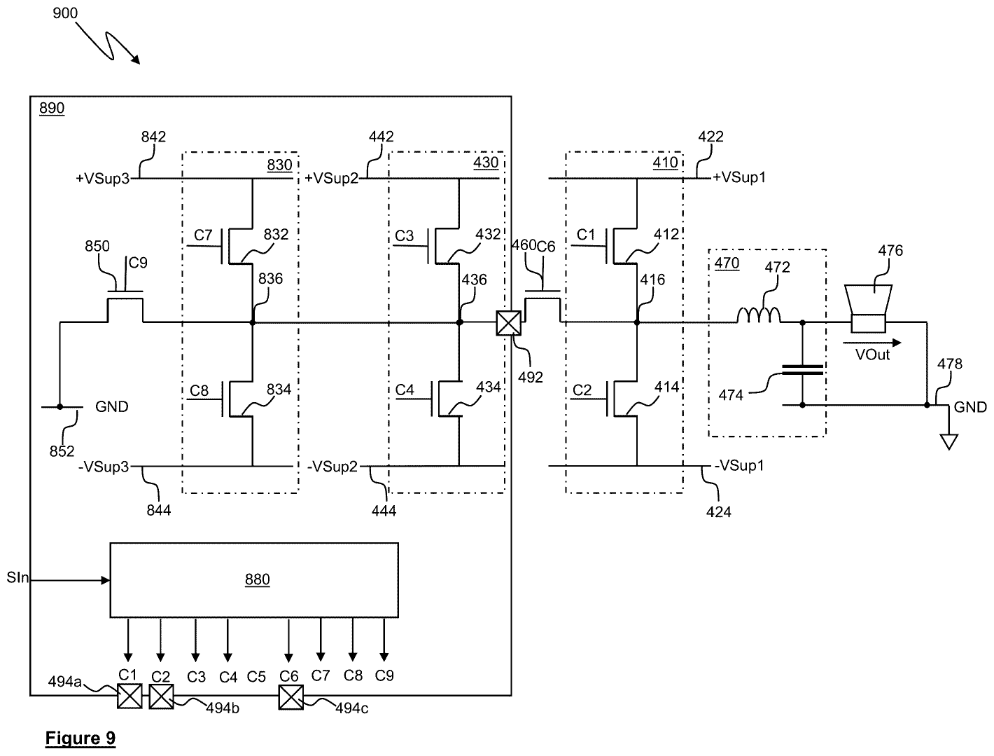

FIG. 9 is a schematic representation of alternative example switching driver circuitry 900 including three half-bridges. The alternative switching driver circuitry 900 is similar to, and includes many features in common with, the switching driver circuitry 800 of FIG. 8. Such common features are denoted by common reference numerals in FIGS. 8 and 9 and will not be described again here for the sake of clarity and brevity.

The alternative switching driver circuitry 900 differs from the switching circuitry 800 of FIG. 8 in that it omits the coupling switch 840. Thus, the output node 436 of the second half-bridge 430 can be coupled to the ground rail 852 by closing (i.e. switching on) the ground switch 850.

In a similar manner to the switching driver circuitry 800 of FIG. 8, the alternative switching driver circuitry 900 is operable in a first (high output power) mode, a second (lower output power) mode and a third (lowest output power) mode, based on the results of comparisons performed by the control circuitry 880 of the level of the input signal SIn to first and second thresholds.

Thus, if the level of the input signal SIn is equal to or greater than the first threshold, the control circuitry 880 may cause the switching driver circuitry 900 to operate in its first mode by outputting a suitable control signal C6 to switch off the isolation switch 460 and outputting suitable control signals C1, C2 to control the first high-side switch 412 and the first low-side switch 414 to generate the required output voltage VOut across the load 476.

If the level of the input signal SIn is lower than the first threshold, but equal to or greater than the second threshold, the control circuitry 880 may may cause the switching driver circuitry 900 to operate in its second mode, by outputting a suitable control signal C6 to switch on the isolation switch 460, and outputting suitable control signals C3, C4, C9 to control the second high-side switch 432, the second low-side switch 434 and the ground switch 850 to generate the required output voltage VOut across the load 476.

If the level of the input signal SIn is lower than the second threshold, the control circuitry 880 may may cause the switching driver circuitry 900 to operate in its third mode, by outputting a suitable control signal C6 to switch on the isolation switch 460, and outputting suitable control signals C7, C8, C9 to control the third high-side switch 832, the third low-side switch 834 and the ground switch 850 to generate the required output voltage VOut across the load 476.

If the level of the input signal is zero (or less than a third threshold that is lower than the second threshold), the control circuitry 880 may output a suitable control signal C6 to switch on the isolation switch 460, and may output suitable control signals C9 to switch on the ground switch 850, and may output suitable control signals C1, C2, C3, C4, C7, C8 to switch off the first high-side switch 412, the first low-side switch 414, the second high-side switch 432, the second low-side switch 434, the third high-side switch 832 and the third low-side switch 834. With the switches 412, 414, 432, 434, 460, 832, 834, 850 in this configuration, the output node 416 of the first half-bridge 410 is coupled to ground, such that no output voltage VOut develops across the load 476.

In the examples shown in FIGS. 8 and 9, first, second and third supply voltages +/−VSup1, +/−VSup2 and +/−VSup3 are required. It will be appreciated by those of ordinarily skill in the art that the second and third supply voltages +/−VSup2, +/−VSup3 could be generated from the first supply voltage +/−VSup1 using two instances of LDO circuitry of the kind described above with reference to FIG. 6, or using two instances of charge pump circuitry of the kind described above with reference to FIG. 7. More generally, in implementations that use more than two half-bridges and thus require a plurality of additional supply voltages, the plurality of additional supply voltages can be generated from the first supply voltage using a plurality of LDOs or a plurality of charge pumps, or a combination of one or more LDOs and one or more charge pumps.

In many applications it is beneficial to use single-ended output stages of the kind described above with reference to FIGS. 4, 5, 8 and 9 to minimise the number of switches required to implement the half-bridges, and to minimise the number of external capacitors and inductors required for low-pass filtering. However, in some applications it may be more beneficial to use a bridge-tied load configuration for the output stage.

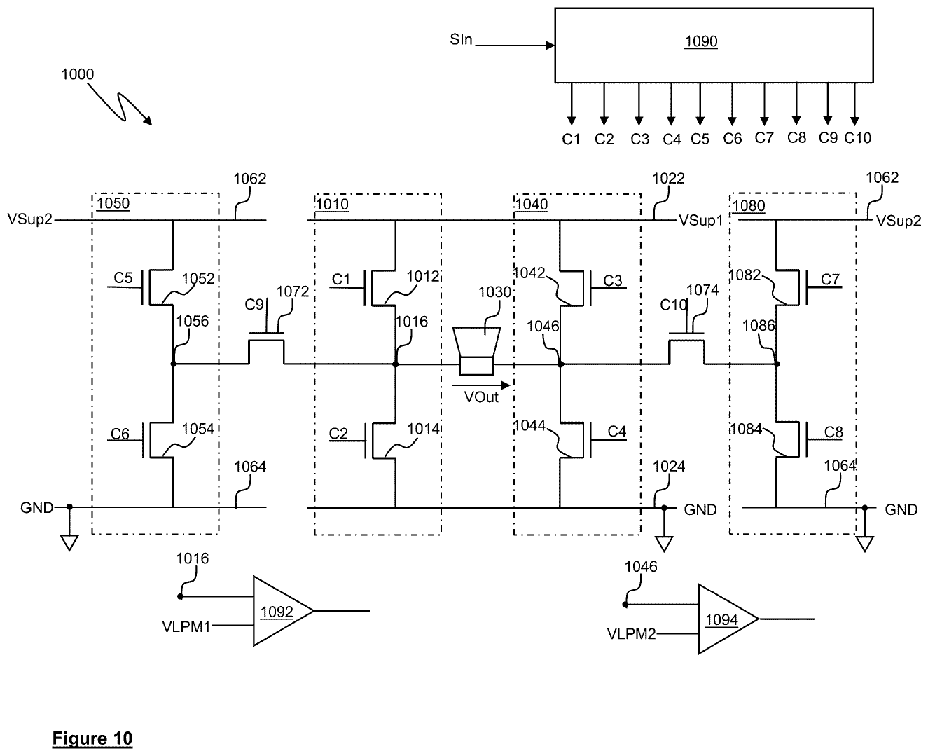

FIG. 10 is a schematic representation of switching driver circuitry according to the present disclosure that uses a bridge-tied load (BTL) configuration.

The switching driver circuitry, shown generally at 1000 in FIG. 10, implements a Class D amplifier output stage. The switching driver circuitry 1000 comprises a first high-power half-bridge 1010, comprising a first high-side switch 1012 and a first low-side switch 1014 coupled in series between a first positive power supply rail 1022 that receives a first positive power supply voltage +VSup1 from a power supply (not shown) and a first ground power supply rail 1024 that receives a first ground (i.e. 0V) power supply voltage GND from the power supply. An output node 1016 of the first high-power half-bridge between the first high-side switch 1012 and the first low-side switch 1014 is coupled, in use of the switching driver circuitry 1000, to a first input terminal of a load 1030, which may be, for example, an audio output transducer such as a speaker. It will be appreciated that a practical implementation the switching driver circuitry 1000 may include first output low-pass LC filter circuitry between the output node 1016 of the first high-power half-bridge 1010 and the first input terminal of the load 1030. Such filter circuitry is not shown in FIG. 10 for the sake of clarity.

The switching driver circuitry 1000 further comprises a second high-power half-bridge 1040, comprising a second high-side switch 1042 and a second low-side switch 1044 coupled in series between the first positive power supply rail 1022 and the first ground power supply rail 1024. An output node 1046 of the second high-power half-bridge 1040 between the second high-side switch 1042 and the second low-side switch 1044 is coupled, in use of the switching driver circuitry 1000, to a second input terminal of the load 1030. Again, it will be appreciated that a practical implementation the switching driver circuitry 1000 may include second output low-pass LC filter circuitry between the output node 1046 of the second high-power half-bridge 1040 and the second input terminal of the load 1030. Such filter circuitry is not shown in FIG. 10 for the sake of clarity. In switching driver circuitry having such output low-pass LC filter circuitry, it will be understood that compensation circuitry may also be included to compensate for mismatch between the first and second output low-pass LC filter circuitry of the BTL configuration, such that when transitioning between different output stages (i.e. different pairs of half-bridges 1010, 1040, 1050, 1080), transient effects at the output such as pops and clicks are eliminated.

The first and second high-power half-bridges 1010, 1040 are configured to switch relatively high voltages. For example, the magnitude of the first positive power supply voltage VSup1 may be of the order of 60 volts or more. The first high-side switch 1012, the first low-side switch 1014, the second high-side switch 1042 and the second low-side switch 1044 are capable of supporting such relatively high voltages. The first high-side switch 1012, the first low-side switch 1014, the second high-side switch 1042 and the second low-side switch 1044 may be, for example, wide bandgap devices or high electron mobility transistor (HEMT) devices based on, for example, Gallium Nitride (GaN), Silicon Carbide (SiC), Gallium Oxide (Ga₂0₃) or other semiconductor materials. In a particular example, the first high-side switch 1012, the first low-side switch 1014, the second high-side switch 1042 and the second low-side switch 1044 are GaN switches.

The switching driver circuitry 1000 further comprises a first low-power half-bridge 1050, comprising a third high-side switch 1052 and a third low-side switch 1054 coupled in series between a second positive power supply rail 1062 that receives a second positive power supply voltage +VSup2 and a second ground power supply rail 1064 that receives a ground (i.e. 0V) power supply voltage GND. An output node 1056 of the first low-power half-bridge 1050 between the third high-side switch 1052 and the third low-side switch 1054 is coupled to an input terminal of a first isolation switch 1072. An output terminal of the first isolation switch 1072 is coupled to the output node 1016 of the first high-power half-bridge 1010.

The switching driver circuitry 1000 further comprises a second low-power half-bridge 1080, comprising a fourth high-side switch 1082 and a fourth low-side switch 1084 coupled in series between the second positive power supply rail 1062 and the second ground power supply rail 1064. An output node 1086 of the second low-power half-bridge 1080 between the fourth high-side switch 1082 and the fourth low-side switch 1084 is coupled to an input terminal of a second isolation switch 1074. An output terminal of the second isolation switch 1074 is coupled to the output node 1046 of the second high-power half-bridge 1040.

The first and second low-power half-bridges 1050, 1080 are configured to switch lower voltages than the first and second high-power half-bridges 1010, 1040. For example, the magnitude of the second power supply voltage VSup2 may be of the order of 12 volts or less. The third high-side switch 1052, the third low-side switch 1054, the fourth high-side switch 1082 and the fourth low-side switch 1084 are capable of supporting such voltages and may be implemented, for example, using silicon-based MOSFETs.

The first isolation switch 1072 is operable to isolate the first low-power half-bridge 1050 from the first high-power half-bridge 1010, such that the first supply voltage VSup (which could damage the switches 1052, 1054 of the first low-power half-bridge 1050) are not transmitted to the first low-power half-bridge 1050. The first isolation switch 1072 is capable of supporting relatively high voltages of the kind supplied by the first positive supply rail 1022. In particular, the first isolation switch 1072 is configured such that, when switched off, such relatively high voltages cannot pass from the first high-power half-bridge 1010 to the first low-power half-bridge 1050. The first isolation switch 1072 may be, for example, a wide bandgap device or a high electron mobility transistor (HEMT) device based on, for example, Gallium Nitride (GaN), Silicon Carbide (SiC), Gallium Oxide (Ga₂0₃) or other semiconductor materials. The first isolation switch 1072 need not be of the same type as the switches 1012, 1014 of the first high-power half-bridge 1010. For example, the switches 1012, 1014 of the first high-power half-bridge 1010 may be GaN switches, and the first isolation switch 1072 may be a SiC switch.

Similarly, the second isolation switch 1074 is operable to isolate the second low-power half-bridge 1080 from the second high-power half-bridge 1040, such that the first supply voltage VSup (which could damage the switches 1082, 1084 of the second low-power half-bridge 1080) are not transmitted to the second low-power half-bridge 1080. The second isolation switch 1074 is capable of supporting relatively high voltages of the kind supplied by the first positive supply rail 1022. In particular, the second isolation switch 1074 is configured such that, when switched off, such relatively high voltages cannot pass from the second high-power half-bridge 1040 to the second low-power half-bridge 1080. The second isolation switch 1074 may be, for example, a wide bandgap device or a high electron mobility transistor (HEMT) device based on, for example, Gallium Nitride (GaN), Silicon Carbide (SiC), Gallium Oxide (Ga₂0₃) or other semiconductor materials. The second isolation switch 1074 need not be of the same type as the switches 1082, 1084 of the second high-power half-bridge 1080. For example, the switches 1082, 1084 of the second high-power half-bridge 1080 may be GaN switches, and the second isolation switch 1074 may be a SiC switch.

The switching driver circuitry 1000 further comprises control circuitry 1090 (which may also be referred to as modulator circuitry) configured to control the operation of the switching driver circuitry 1000 based on an input signal SIn, received by the control circuitry 1090, that represents a signal to be amplified by the switching driver circuitry 1000.

In use of the switching driver circuitry 1000, control signals C1, C2 are supplied by the control circuitry 1090 to control terminals of the first high-side switch 1012 and the first low-side switch 1014, respectively, to control operation of those switches. Similarly, control signals C3, C4 are supplied by the control circuitry 1090 to control terminals of the second high-side switch 1042 and the second low-side switch 1044, respectively, to control operation of those switches, while control signals C5, C6 are output by the control circuitry 1090 to control terminals of the third high-side switch 1052 and the third low-side switch 1054, respectively, control signals C7, C8 are output by the control circuitry 1090 to control terminals of the fourth high-side switch 1082 and the fourth low-side switch 1084, respectively, and control signals C9, C10 are output to control terminals of the first and second isolation switches 1072, 1074, respectively, to control operation of those switches.

The switching driver circuitry 1000 is operable in a first (high-power output) mode in which the first and second isolation switches 1072, 1074 are open (switched off) and the first and second high-power half-bridges 1010, 1040 supply either +VSup1, −VSup1 or 0V to the load 1030. In the first mode, the control signals C9 and C10 are supplied, respectively, to the first and second isolation switches 1072, 1074 to turn the first and second isolation switches 1072, 1074 off, thus decoupling and isolating the first low-power half-bridge 1050 from the first high-power half-bridge 1010, and decoupling and isolating the second low-power half-bridge 1080 from the second high-power half-bridge 1040.

The control signals C1, C2, C3, C4 output by the control circuitry 1090 in the first mode are arranged such that either i) the first high-side switch 1012 and the second low-side switch 1044 are switched on at the same time (with the first low-side switch 1014 and the second high-side switch 1042 being switched off), or ii) the second high-side switch 1042 and the first low-side switch 1014 are switched on at the same time (with the first high-side switch 1012 and the second low-side switch 1044 being switched off), or iii) the first and second high-side switches 1012, 1042 and the first and second low-side switches 1014, 1044 are all switched off, or iv) the first high-side switch 1012 and the second high-side switch 1042 are switched on at the same time (with the first low-side switch 1014 and the second low-side switch 1044 being switched off); or v) the first low-side switch 1014 and the second low-side switch 1044 are switched on at the same time (with the first high-side switch 1012 and the second high-side switch 1042 being switched off).

Thus, in the first mode, the output voltage VOut supplied across the load 1030 by the combination of the first and second high-power half-bridges 1010, 1040 may take one of three values: i) +VSup1 (when the first high-side switch 1012 and the second low-side switch 1044 are switched on), ii) −VSup1 (when the second high-side switch 1042 and the first low-side switch 1014 are switched on), and iii) 0V (when the first and second high-side switches 1012, 1042 and the first and second low-side switches 1014, 1044 are all switched off, or when the first and second high-side switches 1012, 1042 are switched on and the first and second low-side switches 1014, 1044 are switched off, or when the first and second low-side switches 1014, 1044 are switched on and the first and second high-side switches 1012, 1042 are switched off).

In the first output mode, the control signals C5, C6, C7, C8 supplied to the third high-side switch 1052, the third low-side switch 1054, the fourth high-side switch 1082 and the fourth low-side switch 1084, respectively, may cause the third high-side switch 1052, the third low-side switch 1054, the fourth high-side switch 1082 and the fourth low-side switch 1084 to be held open (i.e. switched off).

The switching driver circuitry 1000 is also operable in a second (low-power output mode), in which the first and second isolation switches 1072, 1074 are closed (i.e. switched on) in response to suitable control signals C9, C10, and the combination of the first and second low-power half-bridges 1050, 1080 supplies either +VSup2, −VSup2, or 0V to the load 1030.

In the second, low-power output mode, the control signals C9, C10 are supplied to the first and second isolation switches 1072, 1074, respectively, to turn the first and second isolation switches 1072, 1074 on, thus coupling the output node 1056 of the first low-power half-bridge 1050 to the first terminal of the load 1030 and coupling the output node 1086 of the second low-power half-bridge 1080 to the second terminal of the load 1030.

The control signals C5, C6, C7, C8 output by the control circuitry 1090 in the second, low-power output mode are arranged such that either i) the third high-side switch 1052 and the fourth low-side switch 1084 are switched on at a time (with the third low-side switch 1054 and the fourth high-side switch 1082 being switched off), or ii) the fourth high-side switch 1082 and the third low-side switch 1054 are switched on at a time (with the third high-side switch 1052 and the fourth low-side switch 1084 being switched off), or iii) the third and fourth high side switches 1052, 1082 and the third and fourth low-side switches 1054, 1084 are all switched off, or iv) the third high-side switch 1052 and the fourth high-side switch 1082 are switched on at the same time (with the third low-side switch 1054 and the fourth low-side switch 1084 being switched off); or v) the third low-side switch 1054 and the fourth low-side switch 1084 are switched on at the same time (with the third high-side switch 1052 and the fourth high-side switch 1082 being switched off).

Thus, in the second, low-power output mode, the output voltage VOut supplied across the load 1030 by the combination of the first and second low-power half-bridges 1050, 1080 may take one of three values: i) +VSup2 (when the third high-side switch 1052 and the fourth low-side switch 1084 are switched on), ii) −VSup2 (when the fourth high-side switch 1082 and the third low-side switch 1054 are switched on), and 0V (when the third and fourth high side switches 1052, 1082 and the third and fourth low-side switches 1054, 1084 are all switched off, or when the third and fourth high-side switches 1052, 1082 are switched on and the third and fourth low-side switches 1054, 1084 are switched off, or when the third and fourth low-side switches 1054, 1084 are switched on and the third and fourth high-side switches 1052, 1082 are switched off). In the second mode, the control signals C1, C2, C3, C4 supplied to the first high-side switch 1012, the first low-side switch 1014, the second high-side switch 1042 and the second low-side switch 1044, respectively, may cause the first high-side switch 1012, the first low-side switch 1014, the second high-side switch 1042 and the second low-side switch 1044 to be held open (i.e. switched off).

The control circuitry 1090 is configured to control the mode of operation of the switching driver circuitry 1000 based on a level (e.g. a magnitude or envelope) of the input signal SIn received by the control circuitry 1090. The control circuitry 1090 may be configured to compare the level if the input signal SIn to a first threshold and, based on the result of this comparison, cause the switching driver circuitry 1000 to operate in either its first (high-power output) mode or its second (low-power output) mode.

For example, if the level of the input signal SIn is equal to or greater than the first threshold, this may be indicative that an output voltage VOut across the load 1030 of a magnitude greater than that of the second supply voltage VSup2 is required for the load 1030 to generate an output signal of a desired magnitude (e.g. an audio output of a desired volume) and thus cannot be supplied by the combination of the first and second low-power half-bridges 1050, 1080.

Thus, if the level of the input signal SIn is equal to or greater than the first threshold, the control circuitry 1090 may cause the switching driver circuitry 1000 to operate in its first (high-power output) mode, by outputting suitable control signals C9, C10 to switch off the first and second isolation switches 1072, 1074 and outputting suitable control signals C1, C2, C3, C4 to control the first high-side switch 1012, the first low-side switch 1014, the second high-side switch 1042 and the second low-side switch 1044 to generate the required output voltage VOut across the load 1030.

In contrast, if the level of the input signal SIn is lower than the first threshold, this may be indicative that the magnitude of the output voltage VOut across the load 1030 required for the load 1030 to generate an output signal of a desired magnitude (e.g. an audio output of a desired volume) is less than (or equal to) that of the second supply voltage VSup2 and can thus be supplied by the combination of the first and second low-power half-bridges 1050, 1080.

Thus, if the level of the input signal is less than the first threshold, the control circuitry 1090 may cause the switching driver circuitry 1000 to operate in its second (low-power output) mode, by outputting suitable control signals C9, C10 to switch on the first and second isolation switches 1072, 1074, and outputting suitable control signals C5, C6, C7, C8 to control the third high-side switch 1052, the third low-side switch 1044, the fourth high-side switch 1082 and the fourth low-side switch 1084 to generate the required output voltage VOut across the load 1030.

If the level of the input signal is zero (or less than a second threshold that is lower than the first threshold), this may be indicative that no output signal is required, such that the switching driver circuitry 1000 can operate in a quiescent mode in which no output voltage VOut is supplied to the load 1030.

Thus, if the level of the input signal is zero (or less than the second threshold), the control circuitry 1000 may output suitable control signals C9, C10 to switch on the first and second isolation switches 1072, 1074 and may output suitable control signals C1-C4 to switch off the switches 1012, 1014, 1042, 1044 of the first and second high-power half-bridges 1010, 1040 and may also output suitable control signals C5-C8 to switch off the switches 1052, 1054, 1082, 1084 of the first and second low-power half-bridges 1050, 1080. With the switches 1012, 1014, 1042, 1044, 1052, 1054, 1082, 1084 in this configuration, the output nodes 1016, 1046 of the first and second high-power half-bridges 1010, 1040 are at ground potential, such that no output voltage VOut develops across the load 1030.

Alternatively, the control circuitry 1000 may output suitable control signals C9, C10 to switch on the first and second isolation switches 1072, 1074 and may output suitable control signals C1-C4 to either: i) switch the first and second high-side switches 1012, 1042 on and switch the first and second low-side switches 1014, 1044 off, or ii) switch the first and second high-side switches 1012, 1042 off and switch the first and second low-side switches 1014, 1044 on. In either of these switch configurations, the differential voltage across the load 1030 is 0V.

By selecting between the first (high-power output) mode and the second (low-power output) mode based on the level of the input signal SIn, the switching driver circuitry 1000 of FIG. 10 is capable of efficiently supplying a highly accurate output voltage over a wide range. In particular, operating the Class D amplifier circuitry 1000 in its second (low-power output) mode when the level of the input signal SIn is less than the first threshold (and in the quiescent mode when the input signal level is zero or less than the second threshold) and in its first (high-power output mode) when the level of the input signal SIn is equal to or greater than the first threshold ensures that there is minimal unnecessary headroom in the supply voltage that is switched to provide the output voltage VOut to the load 1030, while also enabling highly accurate control of the magnitude of the output voltage without requiring excessively low duty cycles for the control signals C1-C9 that control the switches 1012, 1014, 1042, 1044, 1052, 1054, 1082, 1084.

It will be appreciated by those of ordinary skill in the art that it may be beneficial to ensure that the output voltage VOut has fallen to a level that can be tolerated by the switches of the third and fourth half-bridges 1050, 1080 before switching from the first (high-power output) mode and the second (low-power output) mode.

Thus, the switching driver circuitry 1000 may further comprise first comparator circuitry 1092 and second comparator circuitry 1094. The first comparator circuitry 1092 is configured to compare the voltage at the output node 1016 of the first high-power half-bridge 1010 to a first low-power output mode threshold VLPM1 (indicative of an output voltage level that can be tolerated by the switches of the first low-power half-bridge 1050), and to prevent the first isolation switch 1072 from being switched on (e.g. by outputting an appropriate first comparator output signal to the control circuitry 1090) unless or until the voltage at the output node 1016 of the first high-power half-bridge 1010 has fallen below the first low-power output mode threshold VLPM1.

Similarly, the second comparator circuitry 1094 is configured to compare the voltage at the output node 1046 of the second high-power half-bridge 1040 to a second low-power output mode threshold VLPM2 (indicative of an output voltage level that can be tolerated by the switches of the second low-power half-bridge 1080, which may be equal to the first low-power output mode threshold VLPM1), and to prevent the second isolation switch 1074 from being switched on (e.g. by outputting an appropriate second comparator output signal to the control circuitry 1090) unless or until the voltage at the output node 1046 of the second high-power half-bridge 1040 has fallen below the second low-power output mode threshold VLPM2.

In some examples, the first and second low-power half-bridges 1050, 1080, the control circuitry 1090 and, optionally, the first and second comparator circuitry 1092, 1094 may be provided on a single IC, while the first and second high-power half-bridges 1010, 1040 and the first and second isolation switches 1072, 1074 are external to the IC. In such examples, the control terminals of switches 1052, 1054, 1082, 1084 of the first and second low-power half-bridges 1050, 1080 may be coupled, internally of the IC, to appropriate outputs of the control circuitry 1090, and the IC may be provided with a first half-bridge output terminal for coupling the output node 1056 of the first low-power half-bridge 1050 to the input terminal of the first external isolation switch 1072, a second half-bridge output terminal for coupling the output node 1086 of the second high-power half-bridge 1080 to the input terminal of the second external isolation switch 1074, and with control output terminals for coupling outputs of the control circuitry 1090 to control terminals of switches 1012, 1014, 1042, 1044 of the external first and second high-power half-bridges 1010, 1040.

In other examples, t the first and second low-power half-bridges 1050, 1080, the control circuitry 1090 and, optionally, the first and second comparator circuitry 1092, 1094 may be provided on a single IC, but the control circuitry 1090 may be external to the IC, as well as the first and second high-power half-bridges 1010, 1040 and the first and second isolation switches 1072, 1074. In such examples, the IC is provided with input terminals for receiving control signals for the switches 1052, 1054, 1082, 1084 of the first and second low-power half-bridges 1050, 1080 from the external control circuitry 1090, and with first half-bridge output terminal for coupling the output node 1056 of the first low-power half-bridge 1050 to the input terminal of the first external isolation switch 1072, a second half-bridge output terminal for coupling the output node 1086 of the second high-power half-bridge 1080 to the input terminal of the second external isolation switch 1074, and with control output terminals for coupling outputs of the control circuitry 1090 to control terminals of switches 1012, 1014, 1042, 1044 of the external first and second high-power half-bridges 1010, 1040.

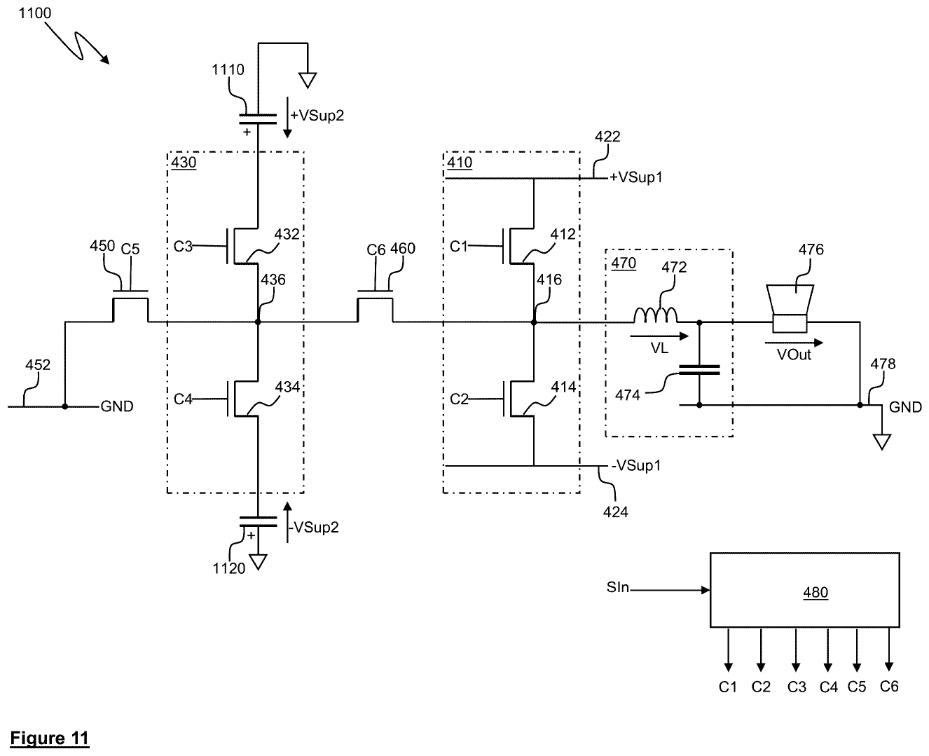

FIG. 11 is a schematic representation of alternative example switching driver circuitry according to the present disclosure, which includes circuitry for generating a second supply voltage form a first supply voltage.

The alternative switching driver circuitry, shown generally at 1100 in FIG. 11, includes a number of features in common with the switching driver circuitry 400 of FIG. 4. Such common features are denoted by common reference numerals in FIGS. 4 and 11 and will not be described again here, for the sake of clarity and brevity.

The switching driver circuitry 1100 differs from the switching driver circuitry 400 of FIG. 4 in that the second half-bridge 430 is coupled between first and second reservoir capacitors 1110, 1120. A first (positive) terminal of the first reservoir capacitor 1100 is coupled to an input terminal of the second high-side switch 432 and a second terminal of the first reservoir capacitor 1110 is coupled to ground, such that a second positive supply voltage +VSup2 can be supplied by the first terminal of the first reservoir capacitor 1110. A first (positive) terminal of the second reservoir capacitor 1120 is coupled to ground, and a second terminal of the second reservoir capacitor 1120 is coupled to an output terminal of the second low-side switch 434, such that a second negative supply voltage −VSup2 can be supplied by the second terminal of the second reservoir capacitor 1120.

The first and second reservoir capacitors 1110, 1120 can be charged up to the second positive and negative supply voltages +/−VSup2, respectively, by using the inductor 472 to store energy from the first supply voltage +/−VSup1 in a charging mode of operation of the switching driver circuitry 1100.

To charge the second reservoir capacitor 1120 to the second negative supply voltage −VSup2, the switching driver circuitry 1100 operates in a plurality of cycles, each cycle comprising a first phase and a second phase.

In the first phase, the first high-side switch 412 is switched on and the first low-side switch 414 and the isolation switch 460 are switched off (in response to suitable control signals C1, C2, C6 output by the control circuitry 480), causing current to flow from the first positive power supply rail 422 through the inductor 472 and load 476 to the ground rail 478, storing energy in the inductor 472.

In the second phase, the first high-side switch 412, the first low-side switch 414 and the second high-side switch 432 are switched off (in response to suitable control signals C1, C2, C3 output by the control circuitry 480), and the isolation switch 460 and the second low-side switch 434 are switched on (in response to suitable control signals C6, C4 output by the control circuitry 480). In this second phase, current flows from the second reservoir capacitor 1120 though the inductor 472 and load 476, causing the voltage −VSup2 to become more negative.

The voltage drop VL across the inductor at the start and end of a cycle of operation is equal to 0. It can be shown that:

$$- VSup 2 = \frac{D}{D - 1} ( VSup 1 - VOut ) ,$$

where D is a duty cycle of the first high-side switch 412.

Thus, the second negative supply voltage −VSup2 is a function of the duty cycle of the first high-side switch 412, the first positive supply voltage +VSup1 and the output voltage VOut.

Similarly, to charge the first reservoir capacitor 1110 to the second positive supply voltage +VSup2, the switching driver circuitry 1100 operates in a plurality of cycles, each cycle comprising a first phase and a second phase.

In the first phase, the first low-side switch 414 is switched on and the first high-side switch 412 and the isolation switch 460 are switched off (in response to suitable control signals C1, C2, C6 output by the control circuitry 480), causing current to flow from the first negative power supply rail 424 through the inductor 472 and load 476 to the ground rail 478, storing energy in the inductor 472.

In the second phase, the first high-side switch 412, the first low-side switch 414 and the second low-side switch 434 are switched off (in response to suitable control signals C1, C2, C3 output by the control circuitry 480), and the isolation switch 460 and the second high-side switch 432 are switched on (in response to suitable control signals C6, C3 output by the control circuitry 480). In this second phase, current flows from the inductor 472 to the first reservoir capacitor 1110, causing the voltage +VSup2 to become more positive.

It can be shown that:

$$VSup 2 = \frac{D}{D - 1} ( - VSup 1 - VOut ) ,$$

where D is a duty cycle of the first low-side switch 414.

Thus, the second positive supply voltage +VSup2 is a function of the duty cycle of the first low-side switch 414, the first negative supply voltage −VSup1 and the output voltage VOut.

In the examples illustrated in FIGS. 4, 5, and 8-11, the high-side switches are shown as being implemented using PMOS devices (or equivalent wide bandgap devices or high electron mobility transistor (HEMT) devices based on, for example, Gallium Nitride (GaN), Silicon Carbide (SiC), Gallium Oxide (Ga203) or other semiconductor materials, for the half-bridges that switch the highest supply voltages). In alternative examples, the high-side switches may instead be implemented as using NMOS devices (or equivalent wide bandgap devices or high electron mobility transistor (HEMT) devices based on, for example, Gallium Nitride (GaN), Silicon Carbide (SiC), Gallium Oxide (Ga203) or other semiconductor materials, for the half-bridges that switch the highest supply voltages), with suitable adaptation of the control signals output by the control circuitry.

The magnitude of the second supply voltage VSup2 may be determined based on a based on a level (e.g. a magnitude or envelope or volume) of the input signal SIn received by the control circuitry 480, and thus the magnitude of the second supply voltage VSup2 may vary dynamically in operation of the switching driver circuitry described above with reference to FIGS. 4, 5 and 8-11.

In the example switching driver circuitry described above with reference to FIGS. 4, 5 and 8-11, when the switching driver circuitry changes from one operating mode to another, using a different half-bridge (or pair of half-bridges, in BTL arrangements of the kind shown in FIG. 10) to switch a different supply voltage, the control (modulator) circuitry that controls the switches of the half-bridges should adapt the duty cycles of the switches according to the supply voltage to be switched in the new operating mode, to prevent the occurrence of artefacts (e.g. audible pops or clicks) in an output of the load.

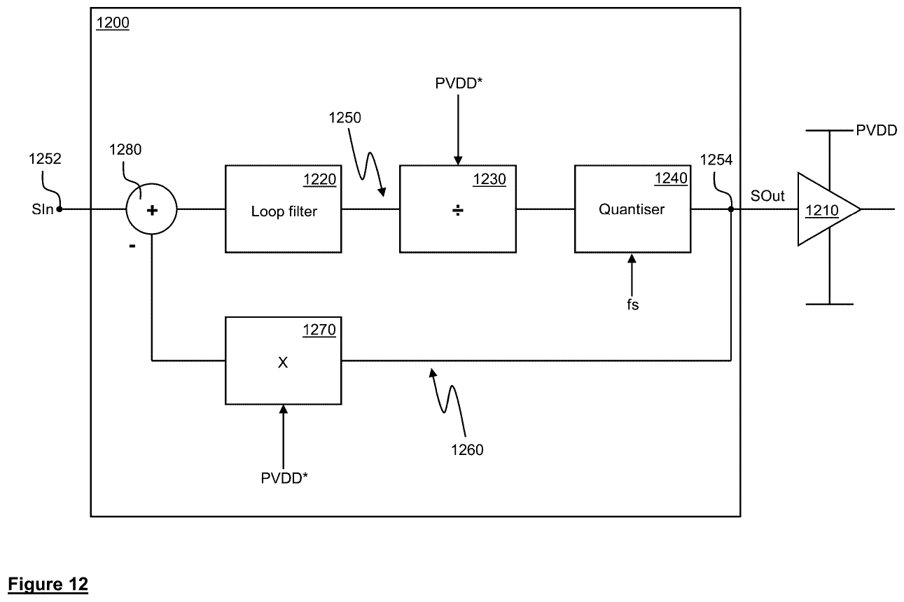

FIG. 12 is a schematic representation of an example digital modulator suitable for use as the control circuitry of the switching driver circuitry described above with reference to FIGS. 4, 5 and 8-11.

In FIG. 12, an amplifier 1210 represents switching driver circuitry of the kind described above described above with reference to FIGS. 4, 5 and 8-11. The modulator, shown generally at 1200, includes a loop filter 1220, a divider 1230, and a quantiser 1240 coupled in a forward path 1250 between an input node 1252 at which an input signal SIn is received and an output node 1254 coupled to the switching driver circuitry 1210 to supply a modulated output signal SOut to the switching driver circuitry 1210.

A feedback path 1260 including a multiplier 1270 couples the output node 1254 to a first input of a subtractor 1280, which is configured to subtract a scaled version of the output signal SOut from the input signal SIn. The result of this subtraction is input to the loop filter 1220.

The quantiser 1240 may be a linear quantiser, in which case the modulator 1200 is a sigma-delta modulator and is followed by a pulse width modulation (PWM) modulator (not shown) coupled to the output of the quantiser to convert sigma-delta codes output by the quantiser 1240 into PWM pulses. Alternatively, the quantiser 1240 may be a PWM quantiser.

The multiplier 1270 in the feedback path 1260 is configured to multiply the output signal SOut by a digital signal PVDD* representing the supply voltage PVDD currently being switched by the half-bridge(s) that are active in the current operating mode of the switching driver circuitry 1210. For example, if the switching driver circuitry 1210 is switching driver circuitry 400 of the kind described above with reference to FIG. 4 and is currently operating in its first (high-power output) mode of operation, PVDD is equal to VSup1, such that PVDD* is a digital signal representative of VSup1. The digital signal PVDD* may be supplied by an analog to digital converter (ADC) coupled to a supply rail of the currently active half-bridge, or may be supplied by a host system incorporating the modulator 1200 and switching driver circuitry 1210. This multiplication ensures that the modulator 1200 supplies controls signals having the correct duty cycle for the current supply voltage PVDD.

The divider 1230 in the forward path is configured to (at least approximately) divide the signal in the forward path by the signal PVDD*, to maintain a noise transfer function (NTF) and loop behaviour of the modulator 1200 within acceptable limits. The divider 1230 may be implemented using a look-up table, for example.

The arrangement of the multiplier 1270 in the feedback path 1270 and the divider 1230 in the forward path 1250 ensures that as PVDD changes (when the switching driver circuitry 1210 changes between operating modes to use different supply voltages) the correct duty cycle is used to control the switches of the half-bridge(s) that is (are) active, and thus prevent the occurrence of artefacts (e.g. audible pops or clicks) in an output signal output by the load.

In the example circuitry described above with reference to FIGS. 4-11, the switches of each half-bridge and the inductor coupled to the output node are subject to relatively large voltage swings, in operation of the circuitry. For example, in the example switching driver circuitry 400 of FIG. 4, a voltage across the first high-side switch 412 of the first half-bridge 410 can swing from +VSup1 to −VSup1, and a voltage across the inductor 472 can similarly swing between +VSup1 and −VSup1. This may result in switching and magnetic losses that are proportional to the square of the voltage swing. In the example switching driver circuitry 400 of FIG. 4, such switching and magnetic losses would be proportional to (2VSup1)².

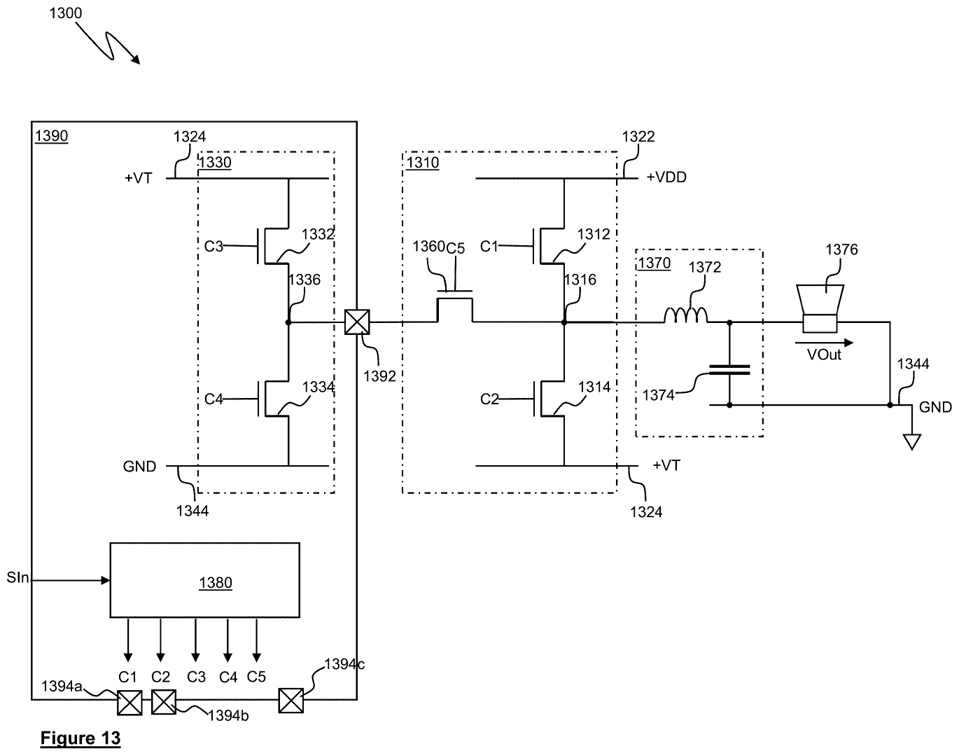

FIG. 13 is a schematic representation of further example switching transducer driver circuitry according to the present disclosure.

In the example shown generally at 1300 in FIG. 13, the switching driver circuitry implements Class D amplifier circuitry, and includes a first half-bridge 1310 comprising a first high-side switch 1312 and a first low-side switch 1314 coupled in series between a positive power supply rail 1322 that receives a first positive power supply voltage having a first magnitude of +VDD from a power supply (not shown) and a second positive power supply rail 1324 that receives an intermediate or threshold voltage having a second magnitude +VT, which is lower than the first magnitude +VDD, from the power supply.

The first half-bridge 1310 is configured to switch relatively high voltages, and may thus be termed a “high-power half-bridge”. The first high-side switch 1312 and the first low-side switch 1314 may be, for example, wide bandgap devices or high electron mobility transistor (HEMT) devices based on, for example, Gallium Nitride (GaN), Silicon Carbide (SiC), Gallium Oxide (Ga203) or other semiconductor materials. In a particular example, the first high-side switch 1312 and the first low-side switch 1314 are GaN switches.

The switching driver circuitry 1300 further includes a second half-bridge 1330 comprising a second high-side switch 1332 and a second low-side switch 1334 coupled in series between the second positive power supply rail 1324 and a reference voltage (e.g. ground) rail 1344 that supplies a reference voltage (e.g. a ground reference voltage, i.e. 0V) having a magnitude that is lower than the magnitude +VT of the intermediate voltage.

The second half-bridge 1330 is configured to switch lower voltages than the first half-bridge 1310, and may thus be termed a “low-power half-bridge”. The second high-side switch 1332 and the second low-side switch 1334 are capable of supporting such voltages and may be implemented, for example, using silicon-based MOSFETs.

The switching driver circuitry 1300 further comprises an isolation switch 1360, having an input terminal coupled to an output node 1336 of the second half-bridge 1330 and an output terminal coupled to an output node 1316 of the first half-bridge 1310, between the first high-side switch 1312 and the first low-side switch 1314. The isolation switch 1360 is operable to isolate the second half-bridge 1330 from the first half-bridge 1310, such that the first positive supply voltage (which could damage the switches 1332, 1344 of the second half-bridge 1330) is not transmitted to the second half-bridge 1330. The isolation switch 1360 is capable of supporting relatively high voltages of the kind supplied by the first positive supply rail 1322. In particular, the isolation switch 1360 is configured such that, when switched off, such relatively high voltages cannot pass from the first half-bridge 1310 to the second half-bridge 1330.

The isolation switch 1360 may comprise, for example, a wide bandgap device or a high electron mobility transistor (HEMT) device based on, for example, Gallium Nitride (GaN), Silicon Carbide (SiC), Gallium Oxide (Ga203) or other semiconductor materials. The isolation switch 1360 need not be of the same type as the switches 1312, 1314 of the first half-bridge 1310. For example, the switches 1312, 1314 of the first half-bridge 1310 may be GaN switches, and the isolation switch 1360 may be a SiC switch.

The isolation switch 1360 may comprise, for example, a HEMT-based back-to-back switch in either a common-source or a common-drain configuration.

In use of the switching driver circuitry 1300, the output node 1316 of the first half-bridge 1310 is coupled, via low-pass filter circuitry 1370 (which comprises an inductor 1372 and a capacitor 1374) to a first terminal of a load 1376, the load 1376 having a second terminal coupled to the reference voltage (e.g. ground) rail 1344.

The switching driver circuitry 1300 further comprises control circuitry 1380 (which may also be referred to as modulator circuitry) configured to control the operation of the switching driver circuitry 1300 based on an input signal SIn, received by the control circuitry 1380, that represents a signal to be amplified by the switching driver circuitry 1300.

In use of the switching driver circuitry 1300, control signals C1, C2 are supplied by the control circuitry 1380 to control terminals of the first high-side switch 1312 and the first low-side switch 1314, respectively, to control operation of the first and second high-side switches 1312, 1314. Similarly, control signals C3, C4 are supplied by the control circuitry 1380 to control terminals of the second high-side switch 1332 and the second low-side switch 1334, respectively, to control operation of the second high-side switch 1332 and the second low-side switch 1334. A further control signal C5 is supplied by the control circuitry 1380 to the isolation switch 1360, to control operation of the isolation switch 1360.

The switching driver circuitry 1300 is operable in a first mode (which may be referred to as a high-power output mode) in which the isolation switch 1360 is open (switched off) and the first half-bridge 1310 supplies either the first positive supply voltage +VDD or the intermediate voltage +VT to the load 1376. In the first mode, the control signal C5 is supplied to the isolation switch 1360 to turn the isolation switch 1360 off, thus decoupling and isolating the second half-bridge 1330 from the first half-bridge 1310. The control signals C1, C2 output by the control circuitry 1380 in the first mode are arranged such that only one of the first high-side switch 1312 and the first low-side switch 1314 can be switched on at once. Thus, in the first mode, the output voltage VOut supplied across the load 1376 by the first half-bridge 1310 may take one of two values: +VDD (when the first high-side switch 1312 is switched on and the first low-side switch 1314 is switched off) or +VT (when the first low-side switch 1314 is switched on and the first high-side switch 1312 is switched off). In the first mode, the control signals C3, C4 supplied to the second high-side switch 1332 and the second low-side switch 1334, respectively, may cause the second high-side switch 1332 and the second low-side switch 1334 to be held open (i.e. switched off).

The switching driver circuitry 1300 is also operable in a second mode (which may be referred to as a low-power output mode), in which the isolation switch 1360 is closed (i.e. switched on) in response to a suitable control signal C5, and the second half-bridge 1330 supplies either the intermediate voltage +VT or the reference voltage (e.g. 0V) to the load 1376. In the second mode, the control signal C5 is supplied to the isolation switch 1360 to turn the isolation switch 1360 on, thus coupling the output node 1336 of the second half-bridge 1330 to the load 1376 (via the low-pass filter 1370). The control signals C3, C4 output by the control circuitry 1380 in the second, low-power output mode are arranged such that only one of the second high-side switch 1332 and the second low-side switch 1334 can be switched on at once. Thus, in the second mode, the output voltage VOut supplied across the load 1376 by the second half-bridge 1330 may take one of two values: +VT (when the second high-side switch 1332 is switched on and the second low-side switch 1334 is switched off) or the reference voltage, e.g. 0V (when the second high-side switch 1332 is switched off and the second low-side switch 1334 is switched on). In the second mode, the control signals C1, C2 supplied to the first high-side switch 1312 and the first low-side switch 1314, respectively, may cause the first high-side switch 1312 and the first low-side switch 1314 to be held open (i.e. switched off).

The control circuitry 1380 is configured to control the mode of operation of the switching driver circuitry 1300 based on an instantaneous level (e.g. a magnitude, envelope or volume) of the input signal SIn received by the control circuitry 1380. The control circuitry 1380 may be configured to compare the level if the input signal SIn to a first threshold and, based on the result of this comparison, cause the switching driver circuitry 1300 to operate in either its first (high-power output) mode or its second (low-power output) mode.

For example, if the level of the input signal SIn is equal to or greater than the first threshold, this may be indicative that an output voltage VOut across the load 1376 of a magnitude greater than that of the intermediate voltage +VT is required for the load 1376 to generate an output signal of a desired magnitude (e.g. an audio output of a desired volume) and thus cannot be supplied by the second half-bridge 1330.

Thus, if the level of the input signal SIn is equal to or greater than the first threshold, the control circuitry 1380 may cause the switching driver circuitry 1300 to operate in its first (high-power output) mode, by outputting a suitable control signal C5 to switch off the isolation switch 1360 and outputting suitable control signals C1, C2 to control the first high-side switch 1312 and the first low-side switch 1314 to generate the required output voltage VOut across the load 1376.

In contrast, if the level of the input signal SIn is lower than the first threshold, this may be indicative that the magnitude of the output voltage VOut across the load 1376 required for the load 1376 to generate an output signal of a desired magnitude (e.g. an audio output of a desired volume) is less than (or equal to) that of the intermediate voltage +VT and can thus be supplied by the second half-bridge 1330.

Thus, if the level of the input signal is less than the first threshold, the control circuitry 1380 may cause the switching driver circuitry 1300 to operate in its second (low-power output) mode, by outputting a suitable control signal C5 to switch on the isolation switch 1360, and outputting suitable control signals C3, C4 to control the second high-side switch 1332 and the second low-side switch 1334 to generate the required output voltage VOut across the load 1376.

If the level of the input signal is zero (or less than a second threshold that is lower than the first threshold), this may be indicative that no output signal is required, such that the switching driver circuitry 1300 can operate in a quiescent mode in which no output voltage VOut is supplied to the load 1376.

Thus, if the level of the input signal is zero (or less than the second threshold), the control circuitry 1380 may output a suitable control signal C5 to switch on the isolation switch 1360, and output a suitable control signal C4 to switch on the second low-side switch 1334, and output suitable control signals C1, C2, C3, to switch off the first high-side switch 1312, the first low-side switch 1314 and the second high-side switch 1332. With the switches 1312, 1314, 1332, 1334, 1360 in this configuration, the output node 1316 of the first half-bridge 1310 is coupled to ground, such that no output voltage VOut develops across the load 1376. This effectively implements a mute mode for extremely small input signals.

By selecting between the first (high-power output) mode and the second (low-power output) mode based on the level of the input signal SIn, the switching driver circuitry 1300 of FIG. 13 is capable of efficiently supplying a highly accurate output voltage over a wide range. In particular, operating the Class D amplifier circuitry 1300 in its second mode when the level of the input signal SIn is less than the first threshold (and in the quiescent mode when the input signal level is zero or less than the second threshold) and in its first mode when the level of the input signal SIn is equal to or greater than the first threshold ensures that there is minimal unnecessary headroom in the supply voltage that is switched to provide the output voltage VOut to the load 1376, while also enabling highly accurate control of the magnitude of the output voltage without requiring excessively low duty cycles for the control signals C1-C4 that control the switches 1312, 1314, 1332, 1334 of the first and second half-bridges 1310, 1330.

Further, because the first half-bridge 1310 and the second half-bridge 1330 handle only those output voltage transitions for which they are optimised (i.e. the first half-bridge 1310 handles only output voltage transitions between +VT and +VDD and the second half-bridge 1330 handles only output voltage transitions between 0V and +VT), the instantaneous voltage swing across the first high-side switch 1312, the first low-side switch 1314 and the inductor 1372 can be reduced, in comparison to the circuitry 400 of FIG. 4, leading to reduced switching losses, inductor core losses and electromagnetic emissions associated with higher voltage swings such as may occur in the circuitry 400 of FIG. 4. This staged multi-level operation preserves the efficiency benefits of using low voltage (e.g. CMOS) devices for small voltage transitions (handled by the second half-bridge 1330), while providing a reduced stress, lower-loss voltage stepping sequence for supplying higher output voltages.

The switching driver circuitry 1300 is further operable in a three-level output mode in which the output node 1316 is switched between the supply voltages supplied by each of the power supply rails 1322, 1324, 1344.

Thus, where an output voltage having a magnitude equal to or greater than +VT and equal to or less than +VDD is required (e.g. if a level of the input signal is greater than some threshold), the isolation switch 1360 may be opened (switched off) in response to a suitable control signal C5 supplied by the control circuitry 1380, and the first half-bridge 1310 may be enabled or activated to supply either the first positive supply voltage +VDD (by switching on the first high-side switch 1312 and switching off the first low-side switch 1314, in response to suitable control signals C1, C2 supplied by the control circuitry 1380) or the intermediate voltage +VT (by switching on the first low-side switch 1314 and switching off the first high-side switch 1312 in response to suitable control signals C2, C1 supplied by the control circuitry 1380) to the load 1376.

Similarly, where an output voltage having a magnitude equal to or greater than 0V (or the reference voltage supplied by the supply rail 1344) and equal to or less than the intermediate voltage +VT is required, the isolation switch 1360 may be closed (switched on) in response to a suitable control signal C5 supplied by the control circuitry 1380, and the second half-bridge 1330 may be enabled or activated to supply either the intermediate voltage +VT (by switching on the second high-side switch 1332 and switching off the second low-side switch 1334 in response to suitable control signals C3, C4 supplied by the control circuitry 1430) or the reference voltage, e.g. 0V (by switching on the second low-side switch 1334 and switching off the first low-side switch 1332 in response to suitable control signals C4, C3 supplied by the control circuitry 1380) to the load 1376.

The control circuitry 1380 may be configured to monitor a voltage at the output node 1316 and to enable the second half-bridge 1330 if the voltage at the output node falls to or below a maximum output voltage that can be supplied by the second half-bridge, e.g. +VT in the example shown in FIG. 13. Additionally or alternatively, the control circuitry 1380 may be configured to enable the second half-bridge 1330 based on the input signal, e.g. to enable the second-half bridge 1330 when a level of the input signal is indicative that an output voltage of between 0V and +VT will be required.

Thus, operation of the switching driver circuitry 1300 in the three-level output mode optimises switching across the whole switching cycle of the switching driver circuitry 1300, to realise the efficiency benefits of using the lower voltage second half-bridge 1330 for small output voltages or output voltage transitions, while ensuring that higher output voltages or output voltage transitions can be supplied or supported by the higher voltage first half-bridge 1310.

In some examples, the second half-bridge 1330 and the control circuitry 1380 may be provided on a single IC 1390, while the first half-bridge 1310 and the isolation switch 1360 are external to the IC 1390. In such examples, the control terminals of the second high-side switch 1332 and the second low-side switch 1334 may be coupled, internally of the IC 1390, to appropriate outputs of the control circuitry 1380, and the IC 1390 may be provided with a half-bridge output terminal 1392 for coupling the output node 1336 to the input terminal of the external isolation switch 1360, and with control output terminals 1394a-1394c for coupling outputs of the control circuitry 1380 to control terminals of the first high-side switch 1312 and the first low-side switch 1314 of the external first half-bridge 1310 and to a control terminal of the external isolation switch 1360.

Thus, such an IC includes an internal half-bridge (the second half-bridge 1330) capable of switching a first voltage (the intermediate voltage +VT) and the control circuitry 1380. The control circuitry 1380 is configured to control operation of the internal half-bridge 1330 and an external half-bridge (the first half-bridge 1310) that is capable of switching a second voltage (the difference between the intermediate voltage +VT and first supply voltage +VDD), which may be of higher magnitude than the first voltage.

Such an IC (which may be referred to as a “bridge driver IC” or simply a “driver IC” or an “amplifier IC”) is thus capable of operation, in relatively low-power applications, as a standalone driver for driving a load such as an audio output transducer (e.g. a speaker), a haptic output transducer (e.g. a resonant actuator) or the like with a two-level signal, or in combination with another such IC in a bridge-tied load configuration for driving such a load. Additionally, because such an IC includes the control circuitry 1380, it is also capable of operation, in higher-power applications, for controlling an external high-power output stage such as the first half-bridge 1310 described above with reference to FIG. 13.

In other examples, the second half-bridge 1330 may be provided on a single integrated circuit (IC) 1390, but the control circuitry 1380 may be external to the IC 1390, as well as the first half-bridge 1310 and the isolation switch 1360. In such examples, the IC 1390 is provided with input terminals for receiving the control signals C3, C4 and C5 for the second high-side switch 1332 and the second low-side switch 1334 from the external control circuitry 1380, and with a half-bridge output terminal 1392 for coupling the output node 1336 to the input terminal of the external isolation switch 1360.

The first half-bridge 1310 may be provided on a further IC, separate to the IC 1330. The further IC may also include the isolation switch 1360.

The switching driver circuitry 1300 may further comprise circuitry of the kind described above with reference to FIGS. 6 and 7 for deriving the intermediate voltage from the first positive power supply voltage (adapted to supply the positive intermediate voltage rather than positive and negative second supply voltages).

In the example shown in FIG. 13, the first half-bridge 1310 is operative to switch the output node 1316 between the first positive supply voltage +VDD and the intermediate voltage +VT, and the second half-bridge 1330 is operative to switch the output node 1316 between the intermediate voltage +VT and the reference voltage (e.g. 0V). In this example the first positive supply voltage +VDD and the intermediate voltage +VT are both positive voltages, and the reference voltage may be 0V. It will be appreciated by those of ordinary skill in the art that in other examples, the first positive supply voltage may be a positive voltage (having a magnitude of +VDD, for example), but the intermediate voltage may be 0V and the reference voltage may be a negative voltage (having a magnitude of −VDD, for example).

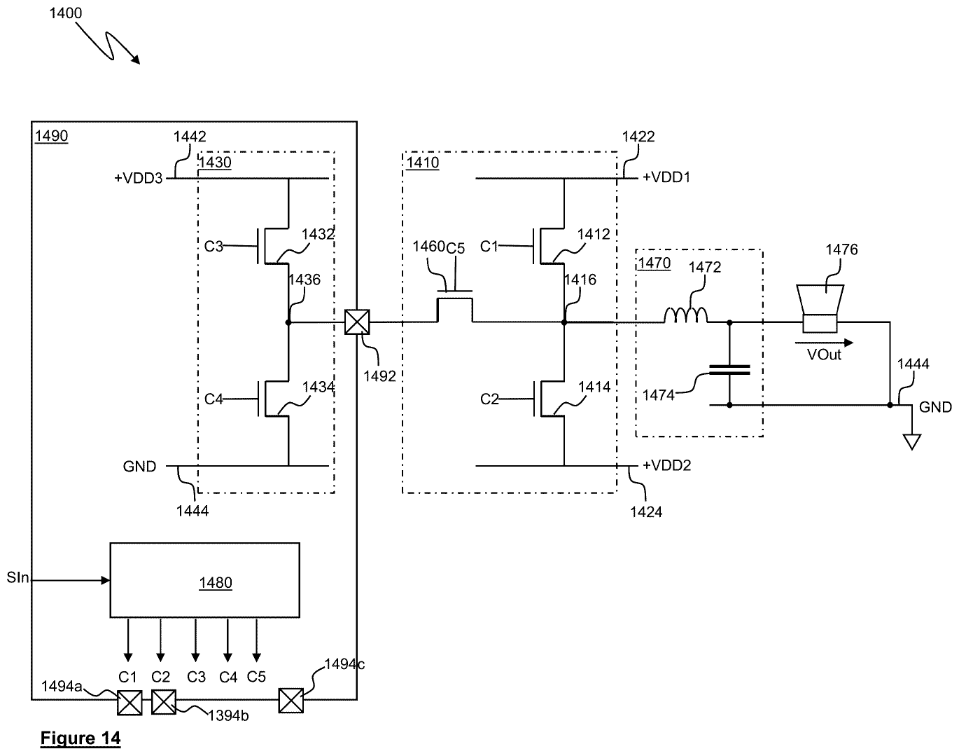

FIG. 14 is a schematic representation of further example switching transducer driver circuitry according to the present disclosure.

In the example shown generally at 1400 in FIG. 14, the switching driver circuitry implements Class D amplifier circuitry, and includes a first half-bridge 1410 comprising a first high-side switch 1412 and a first low-side switch 1414 coupled in series between a first positive power supply rail 1422 that receives a first positive power supply voltage having a first magnitude of +VDD1 (e.g. 48V) from a power supply (not shown) and a second positive power supply rail 1424 that receives second voltage having a second magnitude +VDD2 (e.g. 12V), which is lower than the first magnitude +VDD1, from the power supply.

The first half-bridge 1410 is configured to switch relatively high voltages, and may thus be termed a “high-power half-bridge”. The first high-side switch 1412 and the first low-side switch 1414 may be, for example, wide bandgap devices or high electron mobility transistor (HEMT) devices based on, for example, Gallium Nitride (GaN), Silicon Carbide (SiC), Gallium Oxide (Ga203) or other semiconductor materials. In a particular example, the first high-side switch 1412 and the first low-side switch 1414 are GaN switches.

The switching driver circuitry 1400 further includes a second half-bridge 1430 comprising a second high-side switch 1432 and a second low-side switch 1434 coupled in series between a third positive power supply rail 1442 that receives a third positive power supply voltage having a magnitude +VDD3 (e.g. 10V), which is lower than the second magnitude +VDD2, from the power supply and a ground (0V) or other reference voltage rail 1444 that supplies a ground voltage (or other reference having a magnitude that is lower than the magnitude +VDD3 of the third supply voltage).

The second half-bridge 1430 is configured to switch lower voltages than the first half-bridge 1410, and may thus be termed a “low-power half-bridge”. The second high-side switch 1432 and the second low-side switch 1434 are capable of supporting such voltages and may be implemented, for example, using silicon-based MOSFETs.

The switching driver circuitry 1400 further comprises an isolation switch 1460, having an input terminal coupled to an output node 1436 of the second half-bridge 1430 and an output terminal coupled to an output node 1416 of the first half-bridge 1410, between the first high-side switch 1412 and the first low-side switch 1414. The isolation switch 1460 is operable to isolate the second half-bridge 1430 from the first half-bridge 1410, such that the first positive supply voltage (which could damage the switches 1432, 1444 of the second half-bridge 1330) is not transmitted to the second half-bridge 1430. The isolation switch 1460 is capable of supporting relatively high voltages of the kind supplied by the first positive supply rail 1422. In particular, the isolation switch 1460 is configured such that, when switched off, such relatively high voltages cannot pass from the first half-bridge 1410 to the second half-bridge 1430.

The isolation switch 1460 may comprise, for example, a wide bandgap device or a high electron mobility transistor (HEMT) device based on, for example, Gallium Nitride (GaN), Silicon Carbide (SiC), Gallium Oxide (Ga203) or other semiconductor materials.

The isolation switch 1460 may comprise, for example, a HEMT-based back-to-back switch in either a common-source or a common-drain configuration.

The isolation switch 1460 need not be of the same type as the switches 1412, 1424 of the first half-bridge 1410. For example, the switches 1412, 1424 of the first half-bridge 1410 may be GaN switches, and the isolation switch 1460 may be a SiC switch.

In use of the switching driver circuitry 1400, the output node 1416 of the first half-bridge 1410 is coupled, via low-pass filter circuitry 1470 (which comprises an inductor 1472 and a capacitor 1474) to a first terminal of a load 1476, the load 1476 having a second terminal coupled to the ground rail 1444.

The switching driver circuitry 1400 further comprises control circuitry 1480 (which may also be referred to as modulator circuitry) configured to control the operation of the switching driver circuitry 1400 based on an input signal SIn, received by the control circuitry 1480, that represents a signal to be amplified by the switching driver circuitry 1400.

In use of the switching driver circuitry 1400, control signals C1, C2 are supplied by the control circuitry 1480 to control terminals of the first high-side switch 1412 and the first low-side switch 1414, respectively, to control operation of the first high-side switch and the first low-side switch 1412, 1414. Similarly, control signals C3, C4 are supplied by the control circuitry 1480 to control terminals of the second high-side switch 1432 and the second low-side switch 1434, respectively, to control operation of the second high-side switch 1432 and the second low-side switch 1434. A further control signal C5 is supplied by the control circuitry 1480 to the isolation switch 1460, to control operation of the isolation switch 1460.

The switching driver circuitry 1400 is operable in a four-level output mode in which the output node 1416 is switched between the supply voltages supplied by each of the power supply rails 1422, 1424, 1442, 1444.

Thus, where an output voltage having a magnitude equal to or greater than +VDD2 and equal to or less than +VDD1 is required (e.g. if a level of the input signal is greater than some threshold), the isolation switch 1460 may be opened (switched off) in response to a suitable control signal C5 supplied by the control circuitry 1480, and the first half-bridge 1410 may be enabled or activated to supply either the first positive supply voltage +VDD1 (by switching on the first high-side switch 1412 and switching off the first low-side switch 1414 in response to suitable control signals C1, C2 supplied by the control circuitry 1480) or the second positive supply voltage +VDD2 (by switching on the first low-side switch 1414 and switching off the first high-side switch 1414 in response to suitable control signals C2, C1 supplied by the control circuitry 1480) to the load 1476.

Similarly, where an output voltage having a magnitude equal to or greater than 0V (or the reference voltage supplied by the supply rail 1444) and equal to or less than +VDD3 is required, the isolation switch 1460 may be closed (switched on) in response to a suitable control signal C5 supplied by the control circuitry 1480, and the second half-bridge 1430 may be enabled or activated to supply either the third positive supply voltage +VDD3 (by switching on the second high-side switch 1432 and switching off the second low-side switch 1434 in response to suitable control signals C3, C4 supplied by the control circuitry 1480) or the ground reference voltage (by switching on the second low-side switch 1434 and switching off the second high-side switch 1432 in response to suitable control signals C4, C3 supplied by the control circuitry 1480) to the load 1476.

The control circuitry 1480 may be configured to monitor a voltage at the output node 1416 and to enable the second half-bridge 1430 if the voltage at the output node falls to or below a maximum output voltage that can be supplied by the second half-bridge, e.g. +VDD3 in the example shown in FIG. 4. Additionally or alternatively, the control circuitry 1480 may be configured to enable the second half-bridge based on the input signal, e.g. to enable the second-half bridge 1430 when a level of the input signal is indicative that an output voltage of between 0V and +VDD3 will be required.

Thus, operation of the switching driver circuitry 1400 in the four-level output mode optimises switching across the whole switching cycle of the switching driver circuitry 1400, to realise the efficiency benefits of using the lower voltage second half-bridge 1430 for small output voltages or output voltage transitions, while ensuring that higher output voltages or output voltage transitions can be supplied or supported by the higher voltage first half-bridge 1410.

As in the example switching driver circuitry 1300 of FIG. 13, because the first half-bridge 1410 and the second half-bridge 1430 of the switching driver circuitry 1400 of FIG. 14 handle only those output voltage transitions for which they are optimised (i.e. the first half-bridge 1410 handles only output voltage transitions between +VDD2 and +VDD1 and the second half-bridge 1430 handles only output voltage transitions between 0V and +VDD3), the instantaneous voltage swing across the first high-side switch 1412, the first low-side switch 1414 and the inductor 1472 can be reduced, in comparison to the circuitry 400 of FIG. 4, leading to reduced switching losses, inductor core losses and electromagnetic emissions associated with higher voltage swings such as may occur in the circuitry 400 of FIG. 4. This staged multi-level operation preserves the efficiency benefits of using low voltage (e.g. CMOS) devices for small voltage transitions (handled by the second half-bridge 1430), while providing a reduced stress, lower-loss voltage stepping sequence for supplying higher output voltages.

In some examples, the second half-bridge 1430 and the control circuitry 1480 may be provided on a single IC 1490, while the first half-bridge 1410 and the isolation switch 1460 are external to the IC 1490. In such examples, the control terminals of the second high-side switch 1432 and the second low-side switch 1434 may be coupled, internally of the IC 1490, to appropriate outputs of the control circuitry 1480, and the IC 1490 may be provided with a half-bridge output terminal 1492 for coupling the output node 1436 to the input terminal of the external isolation switch 1460, and with control output terminals 1494a-1494c for coupling outputs of the control circuitry 1480 to control terminals of the first high-side switch 1412 and the first low-side switch 1414 of the external first half-bridge 1410 and to a control terminal of the external isolation switch 1460.

Thus, such an IC includes an internal half-bridge (the second half-bridge 1430) capable of switching a first voltage +VDD3 and the control circuitry 1480. The control circuitry 1480 is configured to control operation of the internal half-bridge 1430 and an external half-bridge (the first half-bridge 1410) that is capable of switching a second voltage (the difference between +VDD2 and +VDD1), which may be of higher magnitude than the first voltage.

Such an IC (which may be referred to as a “bridge driver IC” or simply a “driver IC” or an “amplifier IC”) is thus capable of operation, in relatively low-power applications, as a standalone driver for driving a load such as an audio output transducer (e.g. a speaker), a haptic output transducer (e.g. a resonant actuator) or the like with a two-level signal, or in combination with another such IC in a bridge-tied load configuration for driving such a load. Additionally, because such an IC includes the control circuitry 1480, it is also capable of operation, in higher-power applications, for controlling an external high-power output stage such as the first half-bridge 1410 described above with reference to FIG. 14.

In other examples, the second half-bridge 1430 may be provided on a single integrated circuit (IC) 1490, but the control circuitry 1480 may be external to the IC 1490, as well as the first half-bridge 1410 and the isolation switch 1460. In such examples, the IC 1490 is provided with input terminals for receiving the control signals C3, C4 and C5 for the second high-side switch 1432 and the second low-side switch 1434 from the external control circuitry 1480, and with a half-bridge output terminal 1492 for coupling the output node 1436 to the input terminal of the external isolation switch 1460.

The first half-bridge 1410 may be provided on a further IC, separate to the IC 1430. The further IC may also include the isolation switch 1460.

The switching driver circuitry 1400 may further comprise circuitry of the kind described above with reference to FIGS. 6 and 7 for deriving the intermediate voltage from the first positive power supply voltage (adapted to supply the positive intermediate voltage rather than positive and negative second supply voltages).

The circuitry described above with reference to the accompanying drawings may be incorporated in a host device such as a laptop, notebook, netbook or tablet computer, a gaming device such as a games console or a controller for a games console, a virtual reality (VR) or augmented reality (AR) device, a mobile telephone, a portable audio player or some other portable device, or may be incorporated in an accessory device for use with a laptop, notebook, netbook or tablet computer, a gaming device, a VR or AR device, a mobile telephone, a portable audio player or other portable device.

The skilled person will recognise that some aspects of the above-described apparatus and methods may be embodied as processor control code, for example on a non-volatile carrier medium such as a disk, CD- or DVD-ROM, programmed memory such as read only memory (Firmware), or on a data carrier such as an optical or electrical signal carrier. For many applications embodiments of the invention will be implemented on a DSP (Digital Signal Processor), ASIC (Application Specific Integrated Circuit) or FPGA (Field Programmable Gate Array). Thus the code may comprise conventional program code or microcode or, for example code for setting up or controlling an ASIC or FPGA. The code may also comprise code for dynamically configuring re-configurable apparatus such as re-programmable logic gate arrays. Similarly the code may comprise code for a hardware description language such as Verilog TM or VHDL (Very high speed integrated circuit Hardware Description Language). As the skilled person will appreciate, the code may be distributed between a plurality of coupled components in communication with one another. Where appropriate, the embodiments may also be implemented using code running on a field-(re)programmable analogue array or similar device in order to configure analogue hardware.

Note that as used herein the term module shall be used to refer to a functional unit or block which may be implemented at least partly by dedicated hardware components such as custom defined circuitry and/or at least partly be implemented by one or more software processors or appropriate code running on a suitable general purpose processor or the like. A module may itself comprise other modules or functional units. A module may be provided by multiple components or sub-modules which need not be co-located and could be provided on different integrated circuits and/or running on different processors.

As used herein, when two or more elements are referred to as “coupled” to one another, such term indicates that such two or more elements are in electronic communication or mechanical communication, as applicable, whether connected indirectly or directly, with or without intervening elements.

This disclosure encompasses all changes, substitutions, variations, alterations, and modifications to the example embodiments herein that a person having ordinary skill in the art would comprehend. Similarly, where appropriate, the appended claims encompass all changes, substitutions, variations, alterations, and modifications to the example embodiments herein that a person having ordinary skill in the art would comprehend. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative. Accordingly, modifications, additions, or omissions may be made to the systems, apparatuses, and methods described herein without departing from the scope of the disclosure. For example, the components of the systems and apparatuses may be integrated or separated. Moreover, the operations of the systems and apparatuses disclosed herein may be performed by more, fewer, or other components and the methods described may include more, fewer, or other steps. Additionally, steps may be performed in any suitable order. As used in this document, “each” refers to each member of a set or each member of a subset of a set.

Although exemplary embodiments are illustrated in the figures and described below, the principles of the present disclosure may be implemented using any number of techniques, whether currently known or not. The present disclosure should in no way be limited to the exemplary implementations and techniques illustrated in the drawings and described above.

Unless otherwise specifically noted, articles depicted in the drawings are not necessarily drawn to scale.

All examples and conditional language recited herein are intended for pedagogical objects to aid the reader in understanding the disclosure and the concepts contributed by the inventor to furthering the art, and are construed as being without limitation to such specifically recited examples and conditions. Although embodiments of the present disclosure have been described in detail, it should be understood that various changes, substitutions, and alterations could be made hereto without departing from the spirit and scope of the disclosure.

Although specific advantages have been enumerated above, various embodiments may include some, none, or all of the enumerated advantages. Additionally, other technical advantages may become readily apparent to one of ordinary skill in the art after review of the foregoing figures and description.

It should be noted that the above-mentioned embodiments illustrate rather than limit the invention, and that those skilled in the art will be able to design many alternative embodiments without departing from the scope of the appended claims. The word “comprising” does not exclude the presence of elements or steps other than those listed in a claim, “a” or “an” does not exclude a plurality, and a single feature or other unit may fulfil the functions of several units recited in the claims. Any reference numerals or labels in the claims shall not be construed so as to limit their scope.

1. Switching driver circuitry comprising:
a first half-bridge configured to switch an output node of the switching driver circuitry between a first supply voltage having a first magnitude and a second supply voltage having a second magnitude that is lower than the first magnitude;
a second half-bridge configured to switch the output node between a third supply voltage having a magnitude that is equal to or lower than the second magnitude and a fourth supply voltage having a fourth magnitude that is lower than the third magnitude; and
an isolation switch coupled to the first and second half-bridges and operable to isolate the second half-bridge from the first half-bridge.

2. The switching driver circuitry of claim 1, further comprising control circuitry configured to control operation of the first and second half-bridges and the isolation switch in response to an input signal received by the control circuitry.

3. The switching driver circuitry of claim 2, wherein the switching driver circuitry is operable to switch the output node between either the first supply voltage and the second supply voltage or the third supply voltage and the fourth supply voltage, based on the input signal.

4. The switching driver circuitry of claim 2, wherein the switching driver circuitry is operable in:
a first mode in which the first half-bridge is operable to switch the output node between the first supply voltage and the second supply voltage; and
a second mode in which the second half-bridge is operable to switch the output node between the third supply voltage and the fourth supply voltage,
wherein the control circuitry is configured to control the mode of operation of the switching driver circuitry based on the input signal.

5. The switching driver circuitry of claim 4, wherein the control circuitry is configured to cause the switching driver circuitry to operate in the first mode if a level of the input signal is equal to or greater than a first threshold, and to cause the switching driver circuitry to operate in the second mode if the level of the input signal is less than the first threshold.

6. The switching driver circuitry of claim 1, wherein the first half-bridge comprises a first high-side switch and a first low-side switch, wherein the first high-side switch and the first low-side switch comprise bandgap devices or high electron mobility transistor (HEMT) devices.

7. The switching driver circuitry of claim 8, wherein the first high-side switch and the first low-side switch are Gallium Nitride (GaN) switches.

8. The switching driver circuitry of claim 1, wherein the second half-bridge comprises a second high-side switch and a second low-side switch, wherein the second high-side switch and the second low-side switch comprise CMOS switches.

9. The switching driver circuitry of claim 1, wherein the isolation switch comprises a bandgap device or a high electron mobility transistor (HEMT) device such as a GaN switch.

10. The switching driver circuitry of claim 9, wherein the isolation switch comprises a HEMT-based back-to-back switch in either a common-source or common-drain configuration.

11. An integrated circuit comprising:
a low-power half-bridge comprising a high-side switch and a low-side switch coupled in series; and
a half-bridge output terminal for coupling an output node of the low-power half-bridge to external high-power bridge circuitry,
wherein the half-bridge is configured to switch the half-bridge output terminal between first low-power half-bridge supply voltage and a second low-power half-bridge supply voltage of a magnitude lower than a magnitude of the first low-power half-bridge supply voltage.

12. The integrated circuit of claim 11, wherein the integrated circuit further comprises:
control circuitry configured to control the high-side switch and the low-side switch of the low-power half-bridge and switches of the external high-power bridge circuitry; and
control output terminals for coupling the control circuitry to control terminals of the external high-power bridge circuitry to permit operation of the external high-power bridge circuitry to be controlled by the control circuitry.

13. The integrated circuit of claim 11, wherein the high-side switch and the low-side switch comprise CMOS switches.

14. The integrated circuit of claim 11, wherein the external high-power bridge circuitry comprises a high-power half-bridge comprising a high-side switch and a low-side switch coupled in series,
wherein the high-power half-bridge is configured to switch an output node of the high-power half bridge between a first high-power half-bridge supply voltage and a second high-power half-bridge supply voltage having a magnitude that is greater than the magnitude of the first high-power half-bridge supply voltage,
and wherein the external high-power bridge circuitry further comprises an isolation switch configured to be coupled to the half-bridge output terminal and to selectively isolate the low-power half-bridge from the high-power half-bridge.

15. The integrated circuit of claim 14, wherein the isolation switch comprises a HEMT-based back-to-back switch in either a common-source or common-drain configuration.

16. The integrated circuit of claim 14, wherein the high-side switch and the low-side switch of the external high-power bridge circuitry comprise bandgap devices or high electron mobility transistor (HEMT) devices.

17. The integrated circuit of claim 16, wherein the high-side switch and the low-side switch of the external high-power bridge circuitry are Gallium Nitride (GaN) switches.

18. The integrated circuit of claim 11, wherein the low-power half-bridge is operable to switch the first low-power half-bridge supply voltage and a second low-power half-bridge supply voltage in response to control signals received from control circuitry when a level of an input signal received by the control circuitry is below a first threshold.

19. A host device comprising the integrated circuit of claim 11.

20. A host device according to claim 19, wherein the host device comprises a laptop, notebook, netbook or tablet computer, a gaming device, a games console, a controller for a games console, a virtual reality (VR) or augmented reality (AR) device, a mobile telephone, a portable audio player, a portable device, an accessory device for use with a laptop, notebook, netbook or tablet computer, a gaming device, a games console a VR or AR device, a mobile telephone, a portable audio player or other portable device.
